(19) United States
(12) Patent Application Publication
(10) Pub. No.: US 2026/0047483 A1
(43) Pub. Date: Feb. 12, 2026

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Hyunsoo Chung, Suwon-si (KR); Seungduk Baek, Suwon-si (KR); Chiwoo Lee, Suwon-si (KR)

(21) Appl. No.: 18/798,052

(22) Filed: Aug. 8, 2024

(30) Foreign Application Priority Data
Sep. 1, 2023 (KR) 10-2023-0115948

(51) Int. Cl. H01L 25/16; G02B 6/42; H01L 21/56; H01L 23/00; H01L 23/31; H01L 23/48; H01L 23/538; H01L 25/18; H10B 80/00

(52) U.S. Cl. CPC H01L 25/167; G02B 6/4249; H01L 23/3128; H01L 23/481; H01L 23/5386; H01L 24/16; H01L 25/18; H01L 21/563; H01L 2224/16145; H01L 2224/16227; H01L 2924/1431; H01L 2924/1436; H10B 80/00

(57) ABSTRACT

A semiconductor package includes an interposer that includes a plurality of lower pads and a plurality of upper pads, a first semiconductor chip on the interposer, where the first semiconductor chip includes a first side portion and a second side portion, where the first semiconductor chip includes a first physical layer in a first region that is adjacent to the first side portion and a second physical layer in a second region that is adjacent to the second side portion, a photonic integrated circuit (IC) chip including a plurality of first through vias that at least partially overlap the second region, and an electronic IC chip on the photonic IC chip, where the electronic IC chip includes a third physical layer that at least partially overlaps the second region.

### CROSS-REFERENCE TO RELATED APPLICATION

This application claims priority under 35 U.S.C. § 119 to Korean Patent Application No. 10-2023-0115948, filed on Sep. 1, 2023 in the Korean Intellectual Property Office (KIPO), the contents of which are herein incorporated by reference in their entirety.

### TECHNICAL FIELD

Example embodiments relate to a semiconductor package and a method of manufacturing the semiconductor package. More particularly, example embodiments relate to a semiconductor package having an electronic chip and a photonic chip and a manufacturing method thereof.

### BACKGROUND

With the advancement of artificial intelligence (AI), the amount of data generated, stored, and processed by semiconductor packages is increasing. Accordingly, a co-packaged optics (CPO) including an optical engine including an electronic integrated circuit (EIC) and a photonic integrated circuit (PIC) along with semiconductor chips in one package, is applied. However, in the co-packaged optics, the central processing unit and the optical engine are relatively far apart from each other. Therefore, there may be a problem of increased power consumption due to the relatively long signal connection path.

### SUMMARY

Example embodiments provide a semiconductor package that reduces power consumption.

Example embodiments provide a method of manufacturing the semiconductor package.

According to example embodiments, a semiconductor package includes an interposer that extends in a first direction and includes a plurality of lower pads and a plurality of upper pads, a first semiconductor chip on the interposer, where the first semiconductor chip includes a first side portion and a second side portion that extend in parallel with a second direction that is perpendicular to the first direction, where the first semiconductor chip includes a first physical layer in a first region of the first semiconductor chip that is adjacent to the first side portion and a second physical layer in a second region of the first semiconductor chip that is adjacent to the second side portion, a photonic integrated circuit (IC) chip including a plurality of first through vias that at least partially overlap the second region of the first semiconductor chip a third direction perpendicular to the first direction and the second direction, where a first portion of the photonic IC chip is on the first semiconductor chip, and an electronic IC chip on the photonic IC chip, where the electronic IC chip includes a third physical layer that at least partially overlaps the second region of the first semiconductor chip in the third direction.

According to example embodiments, a semiconductor package includes an interposer that extends in a first direction and includes a plurality of lower pads and a plurality of upper pads, a first semiconductor chip on the interposer, where the first semiconductor chip includes a first side portion and a second side portion that extends in parallel with a second direction that is perpendicular to the first direction, where the first semiconductor chip includes a first physical layer in a first region of the first semiconductor chip that is adjacent to the first side portion and a second physical layer in a second region of the first semiconductor chip that is adjacent to the second side portion, a photonic IC chip including a plurality of first through vias that at least partially overlap the second region of the first semiconductor chip in a third direction perpendicular to the first direction and the second direction, where a first portion of the photonic IC chip is on the first semiconductor chip, and a second semiconductor chip including a fourth physical layer that at least partially overlaps the first region of the first semiconductor chip in the third direction, where a second portion of the second semiconductor chip is on the first semiconductor chip.

According to example embodiments, a semiconductor package includes an interposer that extends in a first direction, the interposer including: a first substrate, a plurality of first lower pads on a backside surface of the first substrate, a plurality of first upper pads on a front surface of the first substrate, and a plurality of first through vias electrically connected to the plurality of first lower pads and to the plurality of first upper pads, a first semiconductor chip including: a second substrate including a first physical layer in a first region of the first semiconductor chip and a second physical layer in a second region of the first semiconductor chip, a plurality of second lower pads on a front surface of the second substrate, a plurality of second upper pads on a backside surface of the second substrate, a plurality of second through vias in the first region and the second region, and first conductive connection members that are respectively between the plurality of first upper pads and the plurality of second lower pads, a photonic IC chip including: an optical fiber array unit that includes a plurality of optical fibers, an optical waveguide configured to transmit an optical signal received from the plurality of optical fibers, an optical element configured to convert the optical signal into an electrical signal, and a plurality of third through vias that at least partially overlap the second region of the first semiconductor chip in a second direction that is perpendicular to the first direction, where a first portion of the photonic IC chip is on the first semiconductor chip, an electronic IC chip including: a third substrate that includes a third physical layer that at least partially overlaps the second region of the first semiconductor chip in the second direction, and a plurality of third lower pads on a front surface of the third substrate, a plurality of third conductive connection members that are respectively between a plurality of third upper pads of the photonic IC chip and the plurality of third lower pads, a second semiconductor chip including: a fourth substrate that includes a fourth physical layer that at least partially overlaps the first region of the first semiconductor chip in the second direction, and a plurality of fourth lower pads on a front surface of the fourth substrate, a plurality of fourth conductive connection members that are respectively between the plurality of second upper pads and the plurality of fourth lower pads, a first die that is on the interposer and is spaced apart from the first semiconductor chip, where a first protruding portion of the photonic IC chip that extends from the first semiconductor chip is on the first die, and a second die that is on the interposer and is spaced apart from the first semiconductor chip, where a second protruding portion of the second semiconductor chip that extends from the first semiconductor chip is on the second die.

According to example embodiments, a semiconductor package may include an interposer, a first semiconductor chip mounted on the interposer and having a first physical layer and a second physical layer, a photonic IC chip having a first portion of the that is mounted on the first semiconductor chip, and an electronic IC chip mounted on the photonic IC chip and having a third physical layer.

The photonic IC chip may have a plurality of first through vias provided in a region overlapped with the second physical layer. The third physical layer of the electronic IC chip may be disposed in a region overlapped with the second physical layer.

Accordingly, a path through which an optical signal introduced from an optical fiber array is transmitted from the photonic IC chip to the first semiconductor chip may be minimized or reduced. Therefore, a power consumption that occurs while the optical signal is transmitted may be reduced.

### BRIEF DESCRIPTION OF THE DRAWINGS

FIG. 1 is a cross-sectional view illustrating a semiconductor package in accordance with example embodiments.

FIG. 2 is a cross-sectional view illustrating signal transmission paths of the semiconductor package in FIG. 1.

FIG. 3 is an enlarged cross-sectional view illustrating the ‘A’ portion of FIG. 1.

FIG. 4 is an enlarged cross-sectional view illustrating the ‘B’ portion of FIG. 1.

FIG. 5 is an enlarged cross-sectional view illustrating the ‘C’ portion of FIG. 1.

FIG. 6 is a cross-sectional view taken along the line D-D′ in FIG. 7.

FIG. 7 is a plan view illustrating a photonic IC chip, a second semiconductor chip, and a first dummy die mounted in a semiconductor package in accordance with example embodiments.

FIGS. 8, 9, 10, 11, 12, 13, 14, 15, 16, 17, 18, 19, 20, 21, 22, 23, 24, 25, and 26 are views illustrating a method of manufacturing a semiconductor package in accordance with example embodiments.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C. ” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

Hereinafter, example embodiments will be explained in detail with reference to the accompanying drawings.

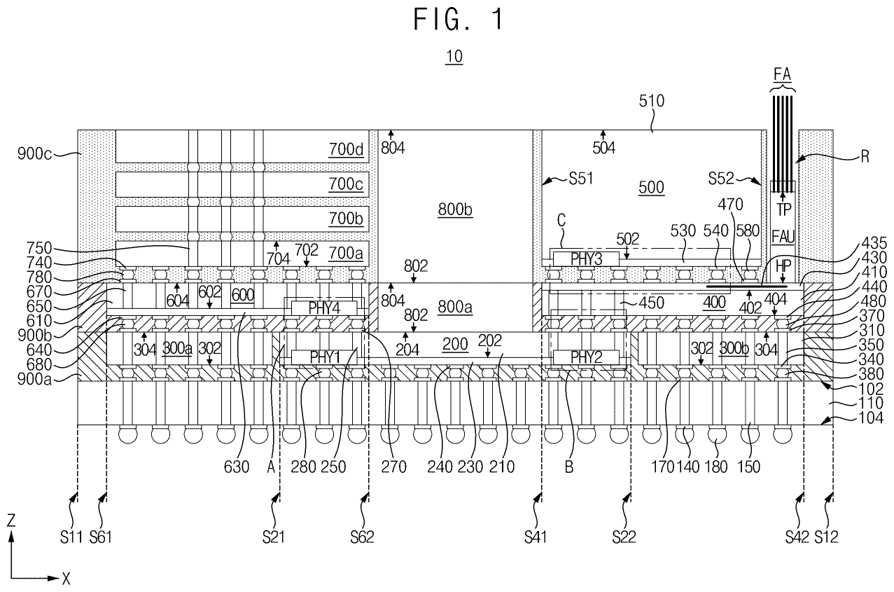

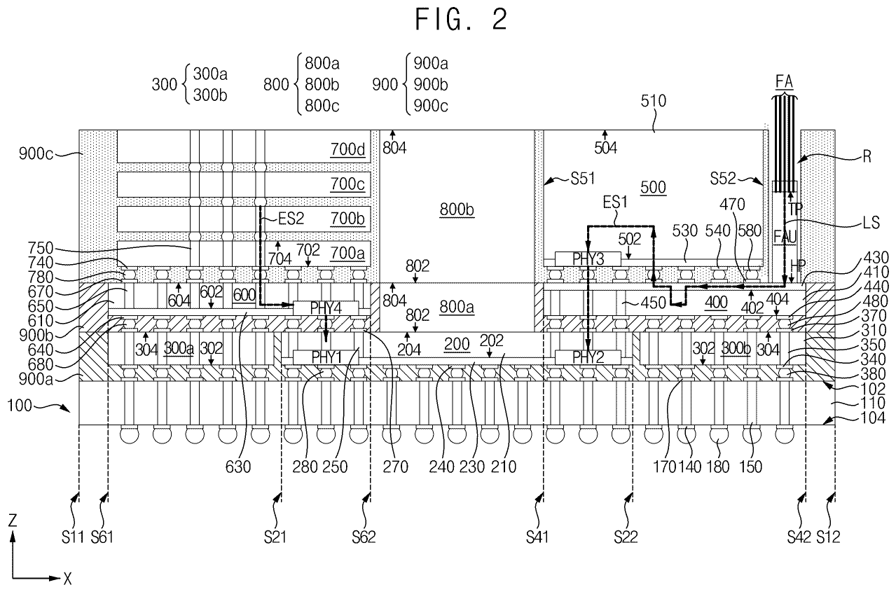

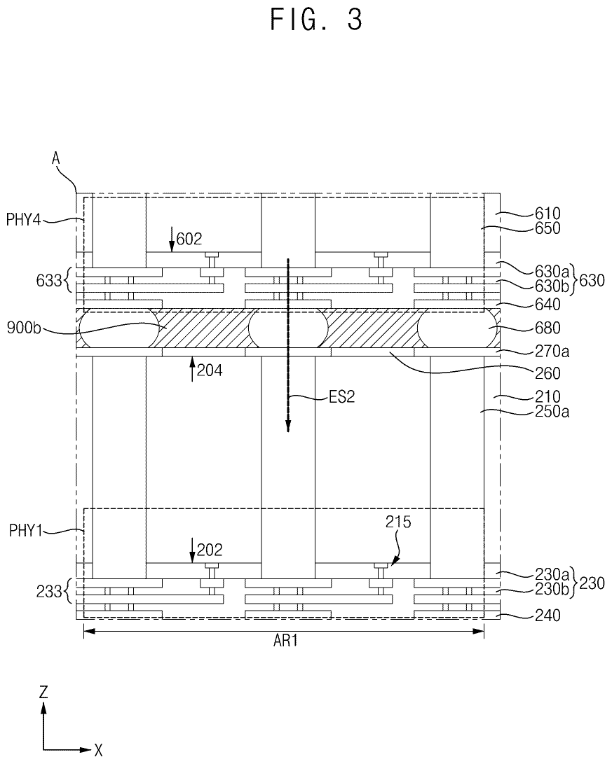

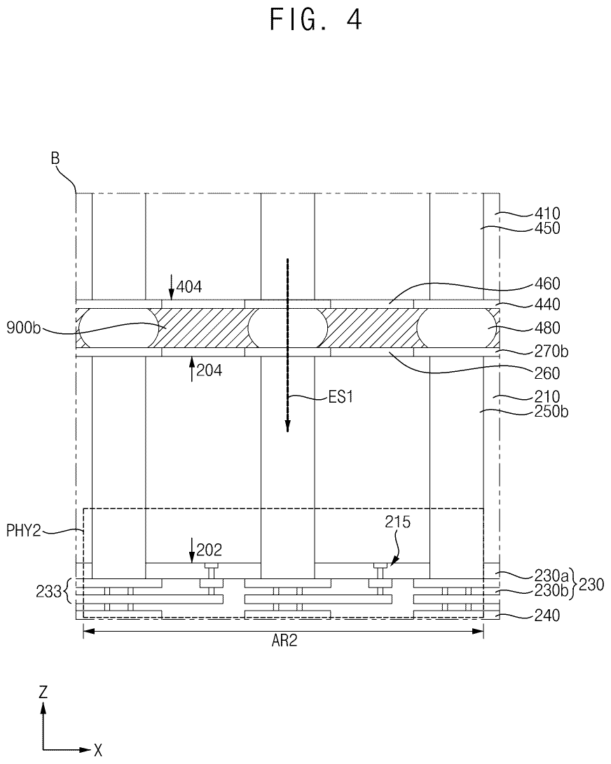

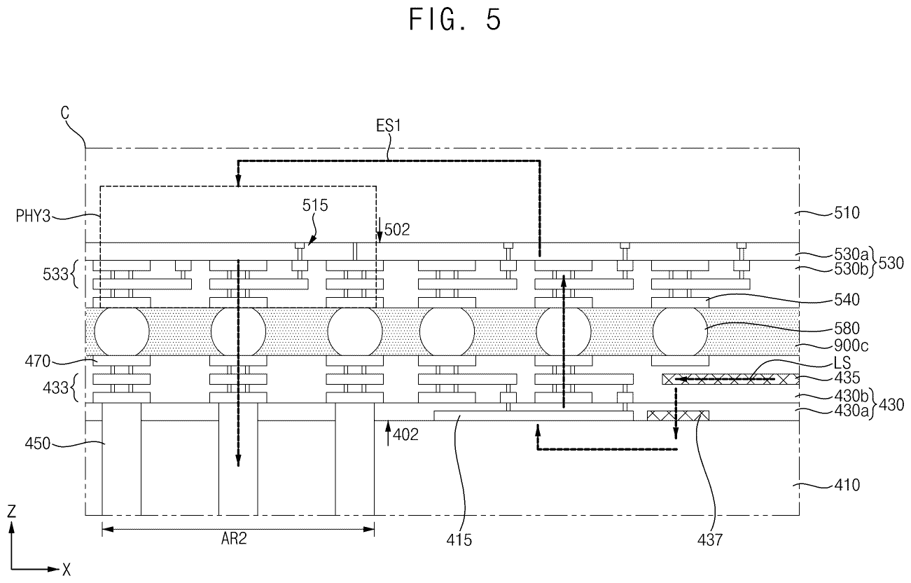

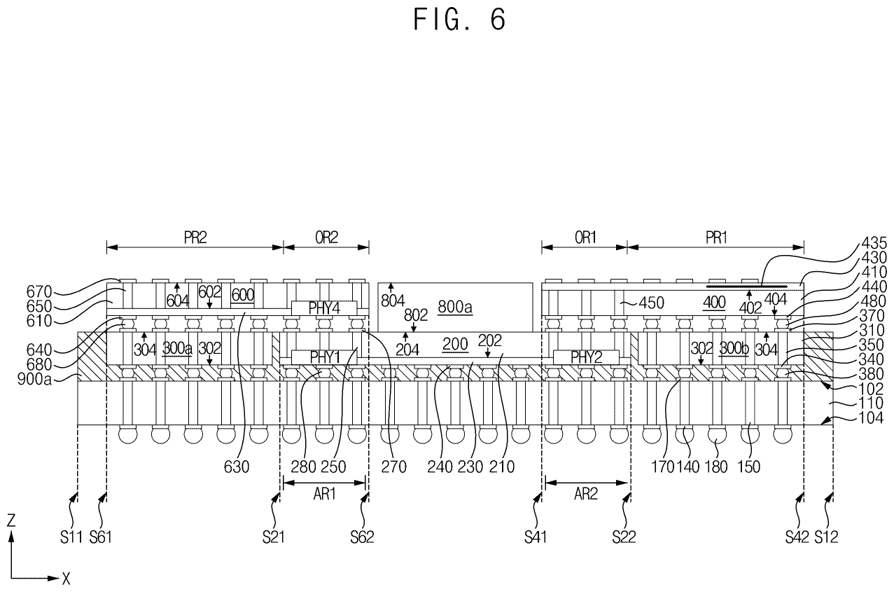

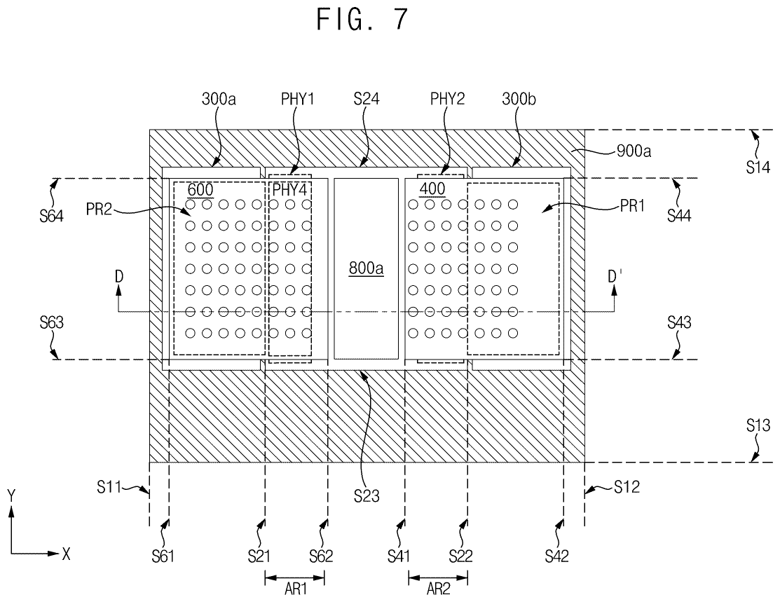

FIG. 1 is a cross-sectional view illustrating a semiconductor package in accordance with example embodiments. FIG. 2 is a cross-sectional view illustrating signal transmission paths of a semiconductor package in accordance with example embodiments. FIG. 3 is an enlarged cross-sectional view illustrating the ‘A’ portion of FIG. 1. FIG. 4 is an enlarged cross-sectional view illustrating the ‘B’ portion of FIG. 1. FIG. 5 is an enlarged cross-sectional view illustrating the ‘C’ portion of FIG. 1. FIG. 6 is a cross-sectional view taken along the line D-D′ in FIG. 7. FIG. 7 is a plan view illustrating a photonic IC chip, a second semiconductor chip, and a first dummy die mounted in the semiconductor package in FIG. 1.

Referring to FIGS. 1 to 7, a semiconductor package 10 may include an interposer 100, a first semiconductor chip 200 mounted on the interposer 100, a plurality of connection dies 300a, 300b (collectively referred to as connection dies 300) stacked on the interposer 100, a photonic integrated circuit (IC) chip 400 stacked on the first semiconductor chip 200 and at least one of the plurality of connection dies 300, an electronic IC chip 500 stacked on the photonic IC chip 400, a second semiconductor chip 600 stacked on the first semiconductor chip 200 and at least one of the plurality of connection dies 300, and a plurality of third semiconductor chips 700 stacked on the second semiconductor chip 600. Additionally, the semiconductor package 10 may further include a plurality of dummy dies 800a, 800b (collectively referred to as dummy dies 800) stacked on the first semiconductor chip 200 and molding members 900a, 900b, 900c (collectively referred to as molding members 900) provided on the interposer 100. Furthermore, the semiconductor package 10 may further include first to seventh conductive connection members 180, 280, 380, 480, 580, 680 and 780.

Additionally, the semiconductor package 10 may be a multi-chip package (MCP) including different types of semiconductor chips. The semiconductor package 10 may be a co-packaged optics (CPO) that includes an optical engine providing an electronic integrated circuit (EIC) and a photonic integrated circuit (PIC) and a system in package (SIP) in one package. The system in package (SIP) may be a package that has an independent function by stacking or arranging a plurality of semiconductor chips in one package.

In example embodiments, the interposer 100 may include a first substrate 110, a plurality of first lower pads 140, a plurality of first through vias 150, a plurality of first upper pads 170 and a plurality of first conductive connection members 180. The interposer may be a silicon interposer having a plurality of wires formed therein. Electronic devices mounted on the interposer may be electrically connected through the plurality of wires. The interposer may provide a high-density interconnection between the electronic devices mounted on the interposer. In some embodiments, the interposer may be a redistribution interposer including a plurality of wirings, a plurality of metal vias and a plurality of insulation layers.

For example, the first substrate 110 may include a front surface 102 and backside surface 104 respectively extending in a first direction (X-direction) and a second direction (Y direction) perpendicular to the first direction (X-direction). The first substrate 110 may include a first side portion S11 and a second side portion S12 extending in the second direction (Y-direction) and facing each other. The first substrate 110 may include a third side portion S13 and a fourth side portion S14 extending in the first direction (X-direction) and facing each other. The first substrate may include a semiconductor material such as silicon, germanium, silicon-germanium, or a group III-V compound semiconductor such as gallium phosphide (GaP), gallium arsenide (GaAs), or gallium antimonide (GaSb).

The plurality of first lower pads 140 may be provided on the backside surface 104 along the XY direction as an array form. For example, the plurality of first lower pads may be conductive pads including a metal material for an electrical connection.

The plurality of first through vias 150 may penetrate or extend into the first substrate 110 to extend from the front surface 102 to the backside surface 104 of the first substrate 110. First end portions of the plurality of first through vias 150 may be respectively in contact with the plurality of first lower pads 140. For example, the plurality of first through vias may include through silicon vias.

The plurality of first upper pads 170 be provided on the front surface 102 along the XY direction as an array form. The plurality of first upper pads may be respectively in contact with second end portions of the plurality of first through vias 150 opposite to the first end portions. For example, the plurality of first upper pads may be conductive pads including a metal material for an electrical connection.

The plurality of first conductive connection members 180 may be respectively provided on the plurality of first lower pads 140. For example, each of the plurality of conductive connection members may be a solder bump including metal material. For example, the interposer 100 may be mounted on a package substrate (not illustrated in the figures) via the plurality of first conductive connection members.

In example embodiments, the first semiconductor chip 200 may include a second substrate 210, a first front insulation layer 230, a plurality of second lower pads 240, a plurality of second through vias 250, a first backside insulation layer 260, the plurality of second upper pads 270 and a plurality of second conductive connection members 280. For example, the first semiconductor chip may be a logic chip including logic circuits. The logic chip may be a controller to control electronic devices mounted on the interposer. The first semiconductor chip may be a processor chip such as an ASIC as a host, such as a CPU, GPU, or SOC, or an application processor (AP).

The first semiconductor chip 200 may be mounted on a central portion of the front surface 102 of the interposer 100. For example, the first semiconductor chip 200 may be mounted on the interposer by a flip chip bonding method. For example, the first semiconductor chip 200 may be mounted on the front surface 102 of the interposer 100 via a plurality of second conductive connection members 280 respectively provided between the plurality of first upper pads 170 and the plurality of second lower pads 240. In this case, the first semiconductor chip 200 may be mounted on the interposer 100 such that the front surface 202 as an active surface where electronic devices are formed faces the interposer 100.

For example, the second substrate 210 may include a front surface 202 and a backside surface 204 respectively extending in the first direction (X-direction) and the second direction (Y direction). The second substrate 210 may include a first side portion S21 and a second side portion S22 extending in the second direction (Y direction) and facing each other. The second substrate 210 may include a third side portion S23 and a fourth side portion S24 extending in the first direction (X-direction) and facing each other.

The second substrate 210 may provide or include a first physical layer PHY1 in a first region AR1 adjacent to the first side portion S21. Additionally, the second substrate 210 may provide or include a second physical layer PHY2 in a second region AR2 adjacent to the second side portion S22.

The physical layer may be an interface region for communication between electronic devices adjacently disposed in one package. For example, the physical layer may be a region for data transmission between various electronic devices such as controller chips such as GPU and CPU, memory devices such as DRAM and an optical engine included in one package. For example, the physical layer may be a region where a plurality of circuits and pads for input/output are provided to exchange data inside a chip.

As illustrate in FIG. 3, the first front insulation layer 230 may cover or overlap the front surface 202 of the second substrate 210. The first front insulation layer 230 may include a first interlayer insulation layer 230a and a second interlayer insulation layer 230b.

The first interlayer insulation layer 230a may include a plurality of electronic devices 215 formed on the front surface 202 of the second substrate 210 therein. For example, the plurality of first electronic devices 215 may be provided on the front surface 202 of the second substrate 210.

The second interlayer insulation layer 230b may have a plurality of first wirings 233 therein. For example, the plurality of first wirings 233 may include a metal material for electrical connection.

The plurality of second lower pads 240 may be provided on the front surface 202 of the second substrate 210. For example, the plurality of second lower pads 240 may be exposed from one side of the second interlayer insulation layer 230b to be electrically connected to the plurality of first wirings 233. For example, the plurality of second lower pads may be conductive pads for electrical connection.

The plurality of second through vias 250 may include first conductive vias 250a and second conductive vias 250b. The plurality of second through vias 250 may be provided in the second substrate 210 to penetrate or extend into the front surface 202 and the backside surface 204 of the second substrate 210. One end portion of each of the plurality of second through vias 250 may contact a portion of the plurality of first wirings 233 connected to the plurality of second lower pads 240. For example, the plurality of second through vias may include through silicon via (TSV).

The plurality of second through vias 250 may be provided in the first region AR1 and the second region AR2. The plurality of first conductive vias 250a may be provided in the first region AR1 to be overlapped with the first physical layer PHY1. The plurality of second conductive vias 250b may be provided in the second region AR2 to be overlapped with the second physical layer PHY2.

The plurality of second upper pads 270 may include a plurality of first conductive pads 270a and a plurality of second conductive pads 270b. The first backside insulation layer 260 may cover or overlap the backside surface 204 of the second substrate 210. For example, the first backside insulation layer 260 may be provided on the backside surface 204 of the second substrate 210 to expose at least one surface of each of the plurality of second upper pads 270. The plurality of second upper pads 270 may be provided on another end portion of each of the plurality of second through vias 250 opposite to the one end portion. For example, the plurality of first conductive pads 270a may be provided on the plurality of first conductive vias 250a, and the plurality of second conductive pads 270b may be provided on the plurality of second conductive vias 250b.

The plurality of second conductive connection members 280 may be provided on each of the plurality of second lower pads 240. For example, the plurality of second conductive connection members may be solder bumps containing or including a metal material.

In example embodiments, a plurality of connection dies 300 may include a first die 300a and a second die 300b. The first die 300a and the second die 300b may include a third substrate 310, a plurality of third lower pads 330, a plurality of third through vias 350, a plurality of third upper pads 370 and a plurality of third conductive connection members 380, respectively.

The plurality of connection dies 300 may be provided on the front surface 102 of the interposer 100 adjacent to the side portions S11 and S12 of the interposer 100 with the first semiconductor chip 200 interposed therebetween. For example, the first die 300a may be spaced apart from the first semiconductor chip 200 in the first direction (X direction) to be disposed adjacent to the first side portion S11 of the interposer 100. The second die 300b may be spaced apart from the first semiconductor chip 200 in the first direction (X direction) to be disposed adjacent to the second side portion S12 of the interposer 100.

The plurality of connection dies 300 may be mounted on the front surface 102 of the interposer 100 via the plurality of third conductive connection members 380 provided between the plurality of first upper pads 170 and the plurality of third lower pads 340, respectively.

For example, the third substrate 310 may have a front surface 302 and a backside surface 304 respectively extending in the first direction (X-direction) and the second direction (Y direction). The plurality of third lower pads 340 may be provided on the front surface 302 along the XY direction as an array form. For example, the plurality of third lower pads may be conductive pads containing or including a metal material for electrical connection.

The plurality of third through vias 350 may vertically penetrate or extend into the third substrate 310 to connect the front surface 302 and the backside surface 304 of the third substrate 310. One end portion of each of the plurality of third through vias 350 may be in contact with each of the plurality of third lower pads 340. For example, the plurality of third through vias may include through silicon via (TSV).

The plurality of third upper pads 370 may be provided on the backside surface 304 along the XY direction as an array form. The plurality of third upper pads 370 may be provided on other end portions of each of the plurality of third through vias 350 that are opposite to the one end portion. For example, the plurality of third upper pads may be conductive pads containing or including a metal material for electrical connection.

The plurality of third conductive connection members 380 may be provided on the plurality of third lower pads 340, respectively. For example, the plurality of third conductive connection members may be solder bumps containing or including a metal material.

In example embodiments, the photonic IC chip 400 may include a fourth substrate 410, a second front insulation layer 430, a plurality of fourth lower pads 440, a plurality of fourth through vias 450, a second backside insulation layer 460, a plurality of fourth upper pads 470 and a plurality of fourth conductive connection members 480. Additionally, the photonic IC chip 400 may include a fiber array unit (FAU). For example, the photonic IC chip may be a photonic integrated circuit (PIC). The PIC may be an optical chip that includes a plurality of optical elements that detect optical signals, transmit the optical signals, and convert the optical signals into electrical signals to process the optical signal.

As illustrated in FIGS. 6 and 7, the photonic IC chip 400 may include a first protruding portion PR1 protruding or extending from the second side portion S22 of the first semiconductor chip 200 and a first overlap portion OR1 excluding the first protruding portion PR1. The first overlap portion OR1 may be mounted on a portion of the backside surface 204 of the first semiconductor chip 200, and the first protruding portion PR1 may be mounted on the second die 300b. For example, the first overlap portion OR1 of the photonic IC chip 400 may be mounted on a region adjacent to the second side portion S22 of the backside surface 204 of the first semiconductor chip 200 by a flip chip bonding method. For example, the first overlap portion OR1 of the photonic IC chip 400 may be mounted on a portion of the backside surface 204 of the first semiconductor chip 200 via a plurality of fourth conductive connection members 480 provided between the plurality of second conductive pads 270b and the plurality of second lower pads 440. In this case, the photonic IC chip 400 may be mounted on the backside surface 204 of the first semiconductor chip 200 such that the backside surface 404 opposite to the front surface as an active surface 402 faces the first semiconductor chip 200.

For example, the fourth substrate 410 may have a front surface 402 and a backside surface 404 respectively extending in the first direction (X-direction) and the second direction (Y direction). The fourth substrate 410 may include a first side portion S41 and a second side portion S42 extending in the second direction (Y direction) and facing each other. The fourth substrate 410 may include a third side portion S41 and a fourth side portion S42 extending in the first direction (X direction) and facing each other.

As illustrated in FIG. 5, the second front insulation layer 430 may cover or overlap the front surface 402 of the fourth substrate 410. The second front insulation layer 430 may include a first interlayer insulation layer 430a and a second interlayer insulation layer 430b.

The first interlayer insulation layer 430a may provide or include a plurality of electronic elements 415 and a plurality of optical elements 437 provided on the front surface 402 of the fourth substrate 410 therein. For example, the plurality of optical elements 437 may include laser diodes to generate optical signals, optical switches to manage a path of the optical signals, optical modulators to modulate the optical signals and transmit data and photodetectors to convert the optical signals into electrical signals. Accordingly, the plurality of optical elements 437 may convert optical signal LS introduced or received from the optical fiber array unit FAU into the first electrical signal ES1. For example, the plurality of second electronic elements 415 may include electronic elements that process and transmit the first electrical signal ES1 converted from the plurality of optical elements 437.

Additionally, the second interlayer insulation layer 430b may have a plurality of second wirings 433 and an optical waveguide 435 therein. The plurality of second wirings 433 and the optical waveguide 435 may be provided in the second interlayer insulation layer 430b. For example, the plurality of second wirings 433 may include a metal material for electrical connection.

The optical waveguide 435 may be an optical path for transmitting the optical signal LS introduced or received from the optical fiber array unit FAU to the plurality of optical elements 437. For example, the second interlayer insulation layer 430b may be a cladding region having a relatively low refractive index, and the optical waveguide 435 may be a core region having a relatively high refractive index.

The plurality of fourth upper pads 470 may be provided on the front surface 402 of the fourth substrate 410. For example, the plurality of fourth upper pads 470 may be exposed from one surface of the second interlayer insulation layer 430b to be electrically connected to the plurality of second wirings 433. For example, the plurality of fourth upper pads may be conductive pads for electrical connection.

The plurality of fourth through vias 450 may be provided to penetrate or extend into the fourth substrate 410 and extend from the front surface 402 to the backside surface 404 of the fourth substrate 410. One end portion of each of the plurality of fourth through vias 450 may be in contact with each of the plurality of second wirings 433 connected to the plurality of fourth upper pads 470. For example, the plurality of fourth through vias may include through silicon via (TSV).

As illustrated in FIG. 4, the plurality of fourth through vias 450 may be provided in the first overlap portion OR1 overlapped with the second region AR2. For example, the plurality of fourth through vias 450 may be provided in a region adjacent to the second side portion S42 overlapped with the second region AR2 of the first semiconductor chip 200. Accordingly, the plurality of fourth through vias 450 may be overlapped with the second physical layer PHY2 and the plurality of second conductive vias 250b provided in the second region AR2 of the first semiconductor chip 200.

The plurality of fourth lower pads 440 may be provided on the backside surface 404 along the XY direction as an array form. The plurality of fourth lower pads 440 may be provided on other end portions of each of the plurality of fourth through vias 450 opposite to the one end portion. For example, the plurality of fourth upper pads may be conductive pads containing or including a metal material for electrical connection. Additionally, the second backside insulation layer 460 may cover or overlap the front surface 402 of the fourth substrate 410. For example, the second backside insulation layer 460 may be provided on the front surface 402 of the fourth substrate 410 to expose at least one surface of the plurality of fourth lower pads 440.

Referring again to FIG. 1, the plurality of fourth conductive connection members 480 may be provided on the plurality of fourth lower pads 440, respectively. For example, the plurality fourth conductive connection members may be a plurality of solder bumps containing or including a metal material.

The optical fiber array unit FAU may be provided on the second front insulation layer 430 adjacent to the second side portion S42 providing the optical waveguide 435. The fiber array unit FAU may include a head portion HP and a tail portion TP opposite to the head portion HP. The optical fiber array unit FAU may be provided on the second front insulation layer 430 such that the head portion HP faces the second front insulation layer 430. For example, the optical fiber array unit FAU may include an optical fiber array FA including a plurality of optical fibers as a medium through which the optical signal LS are transmitted. The optical fiber array FA may be provided on the tail portion TP of the optical fiber array unit FAU. A lens structure for transmitting the optical signal LS to the optical waveguide 435 may be provided on the head TP of the optical fiber array unit FAU.

In example embodiments, the electronic IC chip 500 may include a fifth substrate 510, a third front insulation layer 530, a plurality of fifth lower pads 540, and a plurality of fifth conductive connection members 580. For example, the electronic IC chip may be an electronic integrated circuit EIC. The EIC may convert an analog electrical signal introduced or received from the PIC into a digital electrical signal, and may convert a current electrical signal into a voltage electrical signal, and may be a semiconductor chip including electronic elements that amplify the converted electrical signal.

The electronic IC chip 500 may be mounted on the front surface 402 of the photonic IC chip 400. For example, the electronic IC chip 500 may be mounted on the photonic IC chip 400 by a flip chip bonding method. For example, the electronic IC chip 500 may be mounted on the front surface 402 of the IC chip 400 via the plurality of fifth conductive connection members 580 respectively provided between the plurality of fourth upper pads 470 and the plurality of fifth lower pads 540. In this case, the electronic IC chip 500 may be mounted on the photonic IC chip 400 such that the front surface as an active surface 502 faces the photonic IC chip 400.

For example, the fifth substrate 510 may have a front surface 502 and a backside surface 504 respectively extending in the first direction (X-direction) and the second direction (Y direction). The fifth substrate 510 may include a first side portion S51 and a second side portion S52 extending in the second direction (Y direction) and facing each other. Although not illustrated in the figures, the fifth substrate 510 may include a third side portion S53 and a fourth side portion S51 extending in the first direction (X direction) and facing each other.

The fifth substrate 510 may include a third physical layer PHY3 in a region adjacent to the first side portion S51. Referring to FIG. 5, the third physical layer PHY3 may be overlapped with the second region AR2 in which the second physical layer PHY2 and the plurality of second conductive vias 250b are provided and with which the plurality of fourth through vias 450 are overlapped.

Referring again to FIG. 5, the third front insulation layer 530 may cover or overlap the front surface 502 of the fifth substrate 510. The third front insulation layer 530 may include a first interlayer insulation layer 530a and a second interlayer insulation layer 530b.

The first interlayer insulation layer 530a may include a plurality of electronic devices formed on the front surface 502 of the fifth substrate 510 therein. For example, a plurality of third electronic devices 515 may be provided on the front surface 502 of the fifth substrate 510. The second interlayer insulation layer 530b may provide or include a plurality of third wirings 533 therein. For example, the plurality of third wirings 533 may include a metal material for electrical connection.

The plurality of fifth lower pads 540 may be provided on the front surface 502 of the fifth substrate 510. For example, the plurality of fifth lower pads 540 may be exposed from one side of the second interlayer insulation layer 530b to be electrically connected to the plurality of third wirings 533. For example, the plurality of fifth lower pads may be conductive pads for electrical connection.

The plurality of fifth conductive connection members 580 may be provided on the plurality of fifth lower pads 540, respectively. For example, the plurality of fourth conductive connection members may be solder bumps containing or including a metal material.

As illustrated in FIGS. 2, 4 and 5, the optical signal LS may be transmitted to the first semiconductor chip 200 through the photonic IC chip 400 and the electronic IC chip 500. For example, the optical signal LS introduced or received from the optical fiber array FA may be transmitted to the plurality of optical elements 357 through the optical waveguide 435. The plurality of optical elements 357 may convert the optical signal LS into a first electrical signal ES1. The first electrical signal ES1 may be transmitted to the electronic IC chip 500. For example, the electronic IC chip 500 may amplify the first electrical signal ES1 and convert the current electrical signal into a voltage electrical signal. The first electrical signal ES1 may be transmitted from the third physical layer PHY3 of the electronic IC chip 500 to the first physical layer PHY1 of the first semiconductor chip 200 through the plurality of fourth through vias 450 of the photonic IC chip 400.

In example embodiments, the second semiconductor chip 600 may include a sixth substrate 610, a fourth front insulation layer 630, a plurality of sixth lower pads 640, and a plurality of fifth through vias 650, a plurality of fifth upper pads 670 and a plurality of sixth conductive connection members 680. For example, the second semiconductor chip may be a semiconductor chip that connects electrical signals between a plurality of memory chips and a controller chip and serves as a buffer to organize the electrical signals between a plurality of memory chips and a controller chip.

As illustrated in FIGS. 6 and 7, the second semiconductor chip 600 may include a second protruding portion PR2 protruding or extending from the first side portion S21 of the first semiconductor chip 200 and a second overlap portion OR2 excluding the second protruding portion PR2. The second overlap portion OR2 may be mounted on a portion of the backside surface 204 of the first semiconductor chip 200, and the second protruding portion PR2 may be mounted on the first die 300a. For example, the second overlap portion OR2 of the second semiconductor chip 600 may be mounted on a region adjacent to the first side portion S21 on the backside surface 204 of the first semiconductor chip 200 by a flip chip bonding method. For example, the second overlap portion OR2 of the second semiconductor chip 600 may be mounted on the backside surface 204 of the first semiconductor chip 200 via the plurality of sixth connection members 680 respectively provided between the plurality of first conductive pads 270a and the plurality of sixth lower pads 640. In this case, the second semiconductor chip 600 may be mounted on the backside surface 204 of the first semiconductor chip 200 such that the front surface as an active surface 602 faces the first semiconductor chip 200.

For example, the sixth substrate 610 may have a front surface 602 and a backside surface 604 respectively extending in the first direction (X-direction) and the second direction (Y direction). The sixth substrate 610 may include a first side portion S61 and a second side portion S62 extending in the second direction (Y direction) and facing each other. The sixth substrate 610 may include a third side portion S63 and a fourth side portion S64 extending in the first direction (X direction) and facing each other.

Referring again to FIG. 3, the sixth substrate 610 may include a fourth physical layer PHY4 in the second overlap portion OR2 adjacent to the second side portion S62. The fourth physical layer PHY4 may be overlapped with the first region AR1 providing the first physical layer PHY1 and the plurality of second conductive vias 250b.

The fourth front insulation layer 630 may cover or overlap the front surface 602 of the sixth substrate 610. The fourth front insulation layer 630 may include a first interlayer insulation layer 630a and a second interlayer insulation layer 630b.

The first interlayer insulation layer 630a may provide or include a plurality of electronic devices formed on the front surface 602 of the sixth substrate 610, therein. For example, a plurality of fourth electronic devices 615 may be provided on the front surface 602 of the sixth substrate 610.

The second interlayer insulation layer 630b may provide or include a plurality of fourth wirings 633 therein. For example, the plurality of fourth wirings 633 may include a metal material for electrical connections.

The plurality of sixth lower pads 640 may be provided on the front surface 602 of the sixth substrate 610. For example, the plurality of sixth lower pads 640 may be exposed from one side of the second interlayer insulation layer 630b to be electrically connected to the plurality of fourth wirings 633. For example, the plurality of sixth lower pads may be conductive pads for electrical connections.

The plurality of fifth through vias 650 may be provided in the sixth substrate 610 to penetrate or extend into the front surface 602 and the backside surface 604 of the sixth substrate 610. One end portion of each of the plurality of fifth through vias 650 may be in contact with the plurality of fourth wirings 633 connected to the plurality of sixth lower pads 640. For example, the plurality of fifth through vias may include through silicon via (TSV).

Referring again to FIG. 1, the plurality of fifth upper pads 670 may be provided on the backside surface 604 of the sixth substrate 610. For example, the plurality of fifth upper pads 670 may be provided on other end portions of each of the plurality of fifth through vias 650 opposite to the one end portion.

The plurality of sixth conductive connection members 680 may be respectively provided on the plurality of sixth lower pads 640. For example, the plurality of sixth conductive connection members may be solder bumps containing or including a metal material.

In example embodiments, the plurality of third semiconductor chips 700 may include first to fourth memory chips 700a, 700b, 700c and 700d. The plurality of third semiconductor chips 700 may include a plurality of seventh lower pads 740, a plurality of sixth through vias 750 and a plurality of seventh conductive connection members 780. For example, the plurality of third semiconductor chips may be an electronic device in which memory chips, such as DRAM, are stacked and electrically connected with each other. For example, the plurality of third semiconductor chips may include a plurality of through silicon vias. For example, the second semiconductor chip and the plurality of third semiconductor chips may be a high bandwidth memory (HBM) device.

The plurality of third semiconductor chips 700 may include a first memory chip 700a stacked at a lowest portion and a fourth memory chip 700d stacked at an uppermost portion. The plurality of third semiconductor chips 700 may respectively have an upper surface 704 and a lower surface 702 opposite to the upper surface 704.

The plurality of third semiconductor chips 700 may be mounted on the backside surface 604 of the second semiconductor chip 600. For example, the plurality of third semiconductor chips 700 may be mounted on the second semiconductor chip 600 by a flip chip bonding method. For example, the plurality of third semiconductor chips 700 may be mounted on the backside surface 604 of the second semiconductor chip 600 via a plurality of seventh conductive connection members 780 respectively provided between the plurality of fifth upper pads 670 and the plurality of seventh lower pads 740. In this case, the lower surface 702 of the plurality of third semiconductor chips 700 may be mounted on the second semiconductor chip 600 such that the lower surfaces 702 of the plurality of third semiconductor chips 700 faces the second semiconductor chip 600.

The plurality of seventh lower pads 740 may be provided on the lower surface 702 of the first memory chip 700a. For example, the plurality of seventh lower pads may be conductive pads for electrical connection.

The plurality of sixth through vias 750 may be provided in the center portion of the plurality of third semiconductor chips 700 to penetrate or extend into the upper surface 704 and the lower surface 702 of the plurality of third semiconductor chips 700, respectively.

The plurality of seventh conductive connection members 780 may be respectively provided on end portions of the plurality of seventh lower pads 740 and end portions of the plurality of sixth through vias 750. For example, the plurality of seventh conductive connection members may be solder bumps containing or including a metal material.

In example embodiments, the plurality of dummy dies 800 may include a first dummy die 800a and a second dummy die 800b. The first dummy die 800a and the second dummy die 800b may have a lower surface 802 and an upper surface 804 facing the lower surface 802, respectively.

The plurality of dummy dies 800 may be stacked on the backside surface 204 of the first semiconductor chip 200. For example, the first dummy die 800a may be stacked on the backside surface 204 of the first semiconductor chip 200 such that the lower surface 802 of the first dummy die 800a faces the first semiconductor chip 200. Additionally, the second dummy die 800b may be stacked on the upper surface 804 of the first dummy die 800a such that the lower surface 802 of the second dummy die 800b faces the first semiconductor chip 200.

The first dummy die 800a and the second dummy die 800b may be provided between the first side portion S41 of the photonic IC chip 400 and the second side portion S62 of the second semiconductor chip 600.

The upper surface 804a of the first dummy die 800a may be coplanar with the front surface 402 of the photonic IC chip 400 and the backside surface 604 of the second semiconductor chip 600. The upper surface 804b of the second dummy die 800b may be coplanar with the backside surface 504 of the electronic IC chip 500 and the upper surface 704 of the fourth memory chip 700d among the plurality of third semiconductor chips 700.

In example embodiments, the molding member 900 may include first to third molding portions 900a, 900b and 900c. For example, the molding member 900 may include a thermosetting resin such as an epoxy molding compound (EMC) material.

The first molding portion 900a may be stacked on the backside surface 104 of the interposer 100 to cover or overlap the first semiconductor chip 200 and the plurality of connection dies 300. The second molding portion 900b may be stacked on the first molding portion 900a to cover or overlap the photonic IC chip 400, the second semiconductor chip 600, and the first dummy die 800a. The third molding portion 900c may be stacked on the second molding portion 900b to cover or overlap the electronic IC chip 500, the plurality of third semiconductor chips 700 and the second dummy die 800b.

The third molding portion 900c may expose the backside surface 504 of the electronic IC chip 500, the upper surface 704 of the fourth memory chip 700d among the plurality of third semiconductor chips 700 and the upper surface 804 of the second dummy die 800b. Additionally, the third molding portion 900c may include a recess R exposing a portion of the second front insulation layer 430 of the photonic IC chip 400. For example, the recess R may be provided on a region adjacent to the second side portion S42 where the optical waveguide 435 is provided. The fiber array unit (FAU) may be provided in the recess R.

As mentioned above, the semiconductor package 10 may include the interposer 100, the first semiconductor chip 200 mounted on the interposer 100 and having the first physical layer PHY1 and the second physical layer PHY2, the photonic IC chip 400 having a first portion mounted on the first semiconductor chip 200, and the electronic IC chip 500 mounted on the photonic IC chip 400 and having the third physical layer PHY3.

The photonic IC chip 400 may have the plurality of fourth through vias 450 provided in the region overlapped with the second physical layer PHY2. The third physical layer PHY3 of the electronic IC chip 500 may be disposed in the region overlapped with the second physical layer PHY2.

Accordingly, the electrical path through which the optical signal LS introduced or received from the optical fiber array FA is transmitted from the photonic IC chip 400 to the first semiconductor chip 200 may be minimized or reduced. Therefore, a power consumption that occurs while the optical signal is transmitted may be reduced.

Hereinafter, a method of manufacturing the semiconductor package of FIG. 1 will be described.

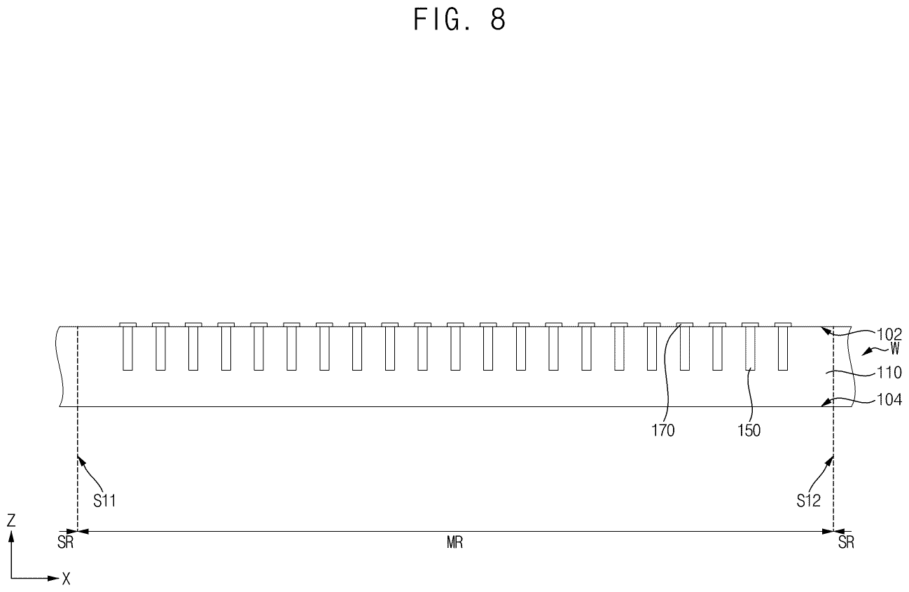

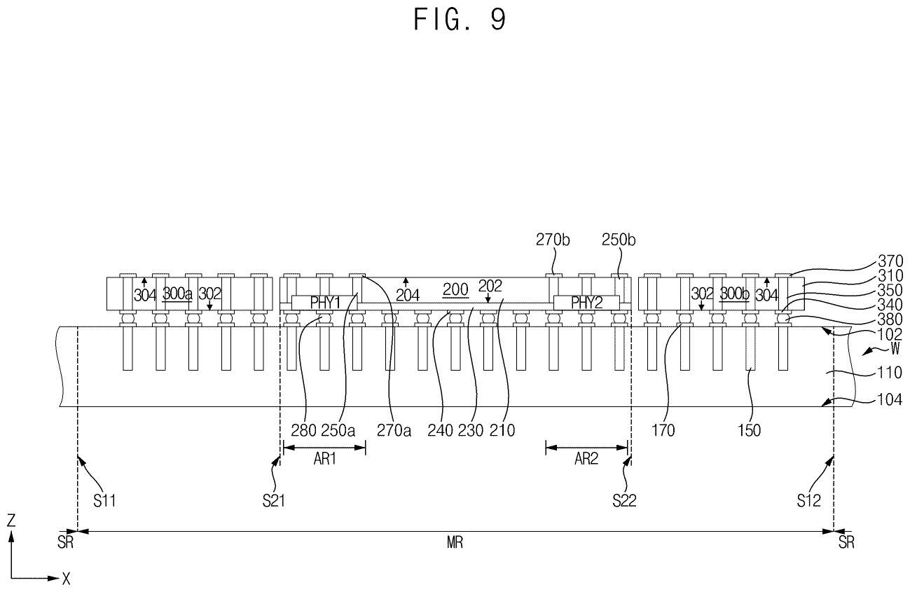

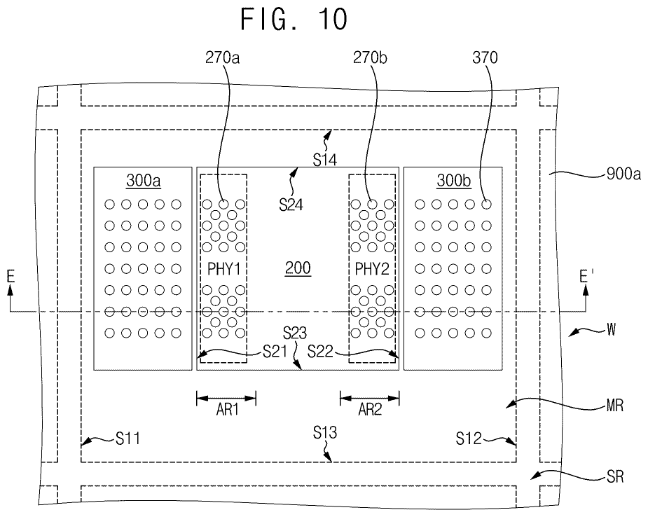

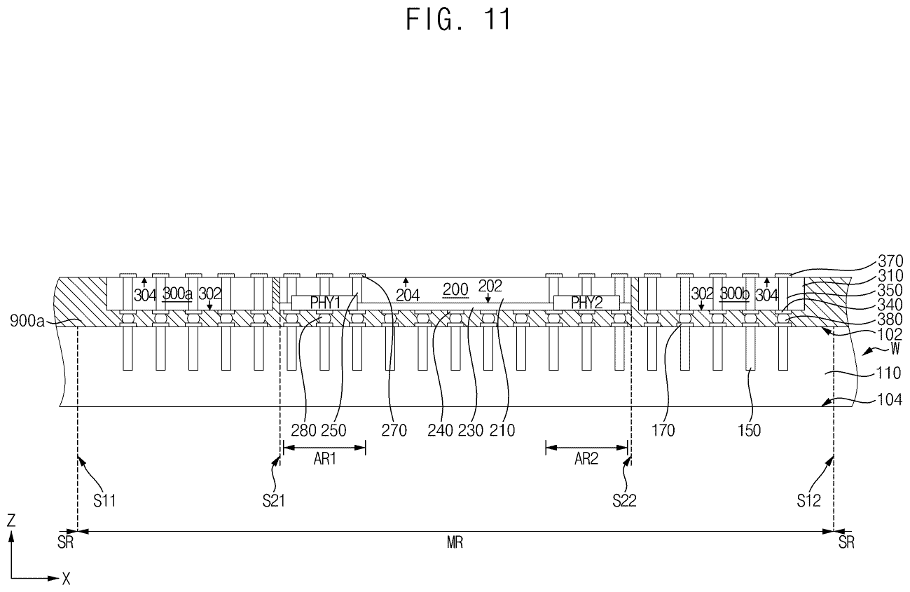

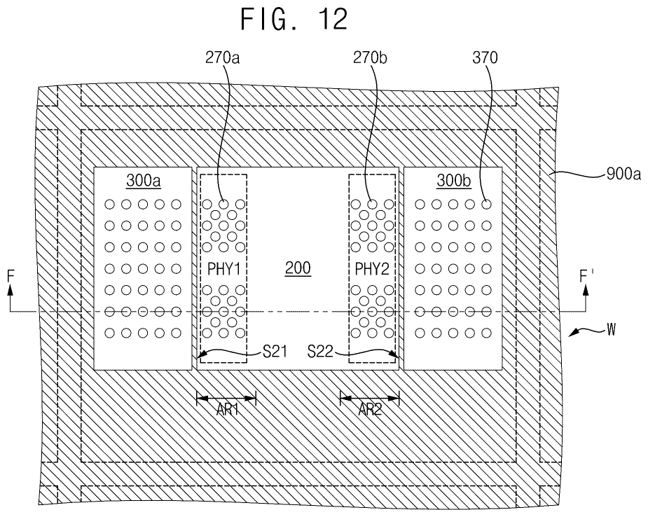

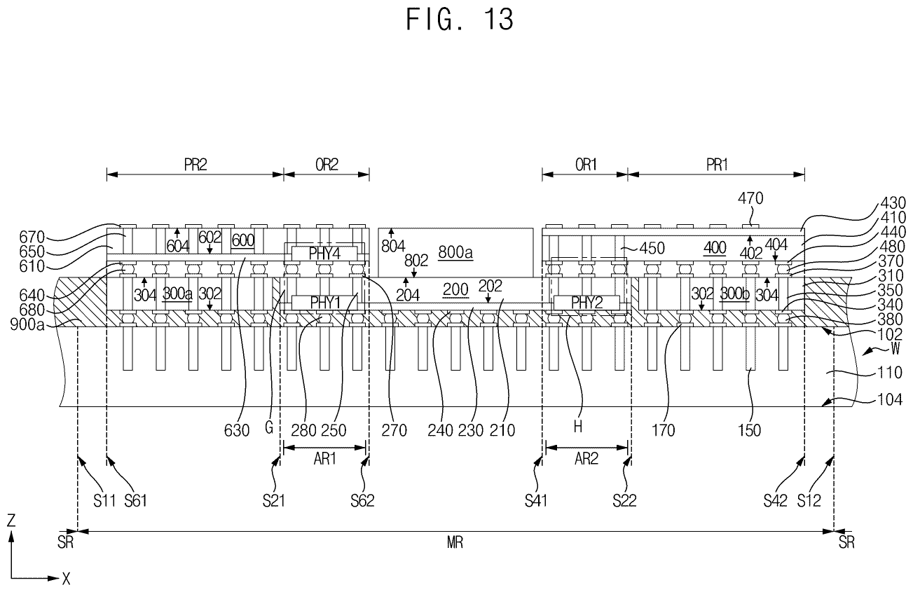

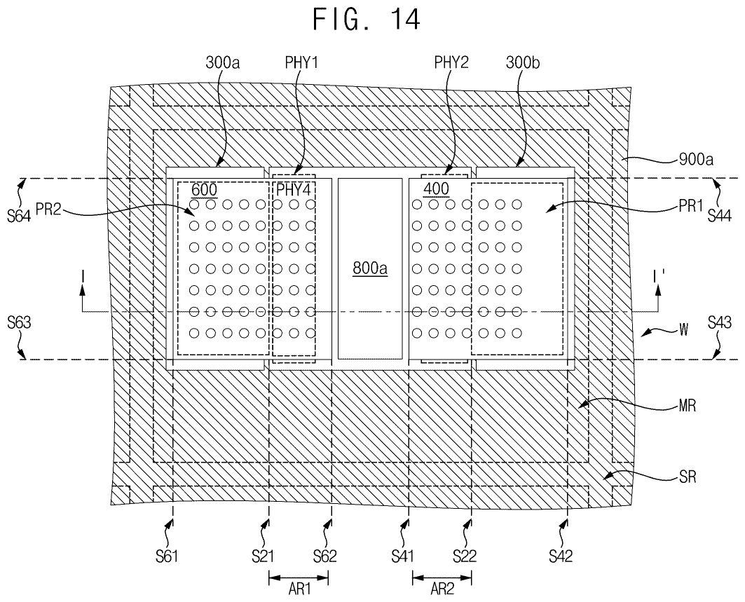

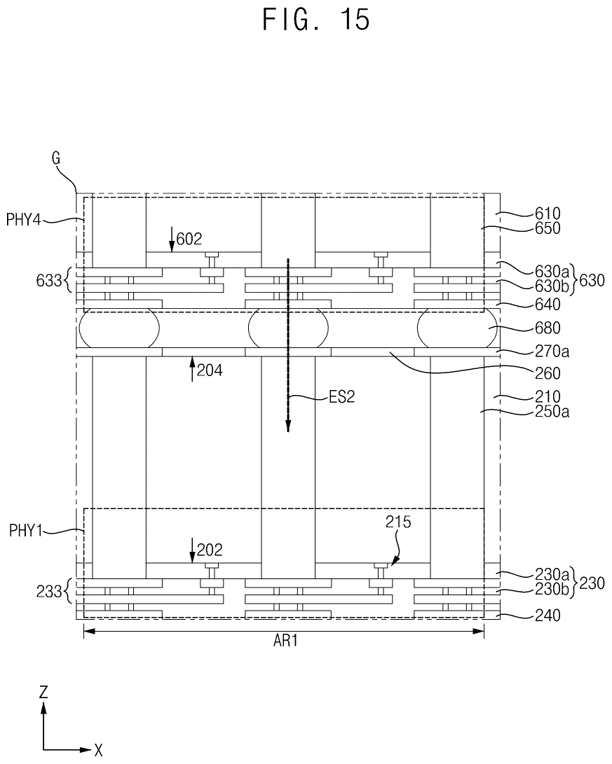

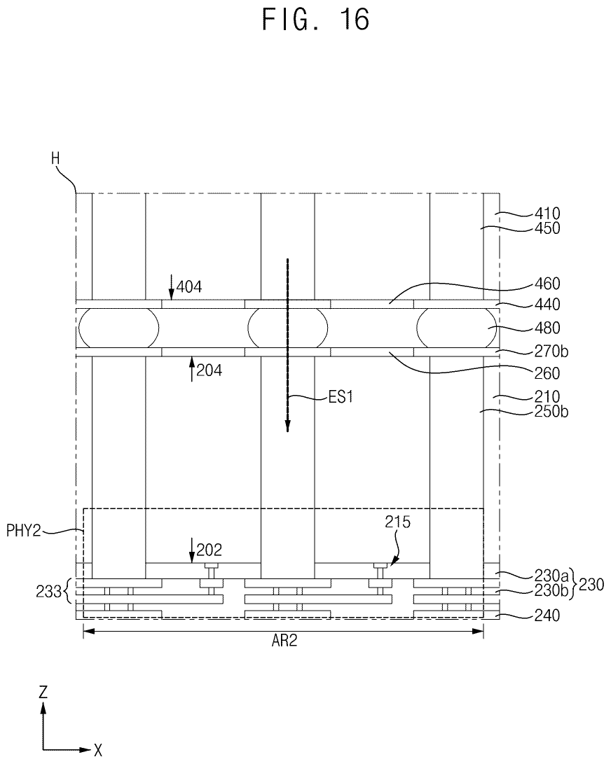

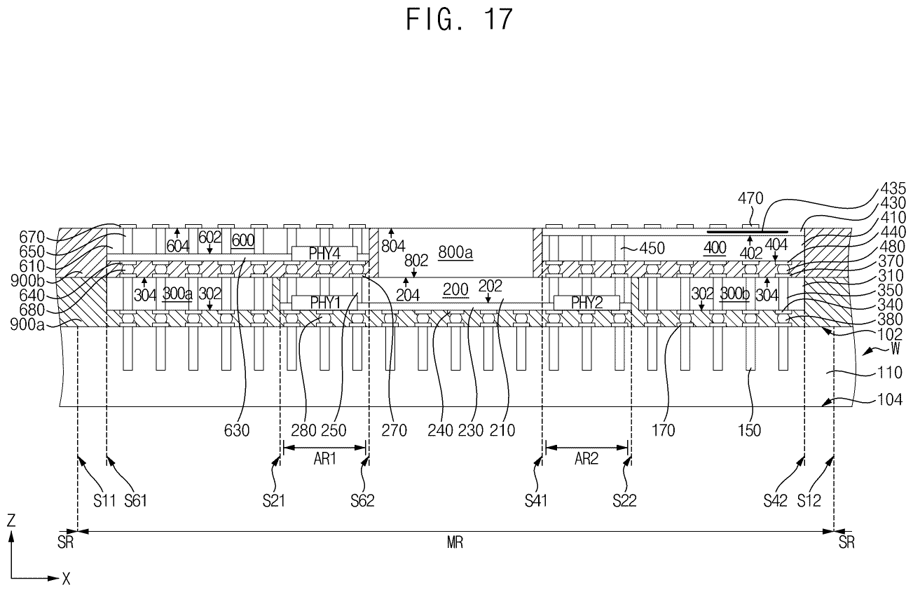

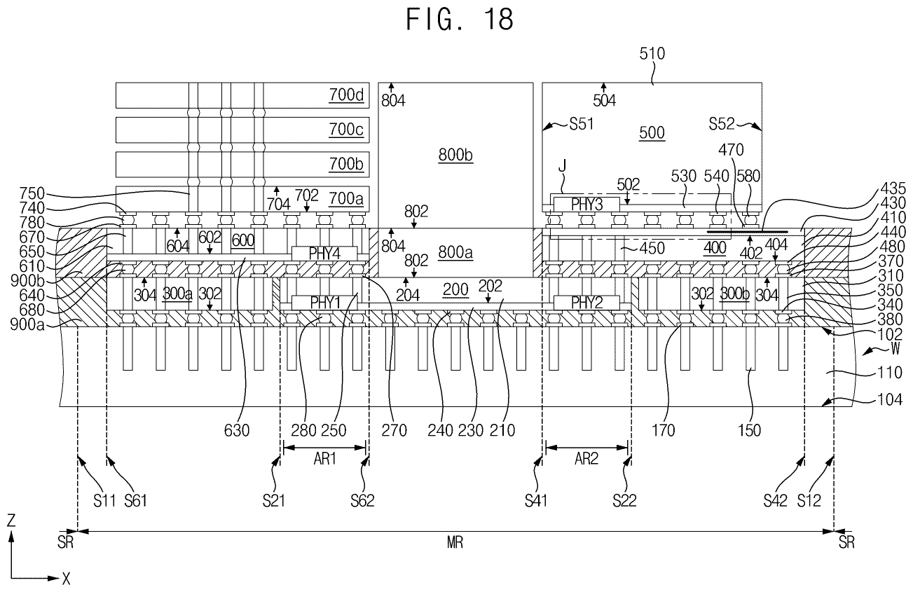

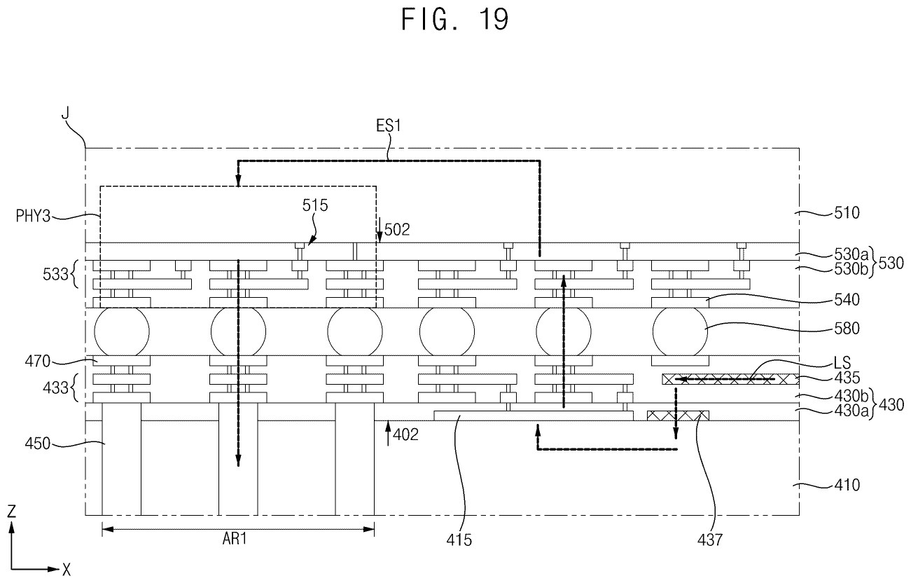

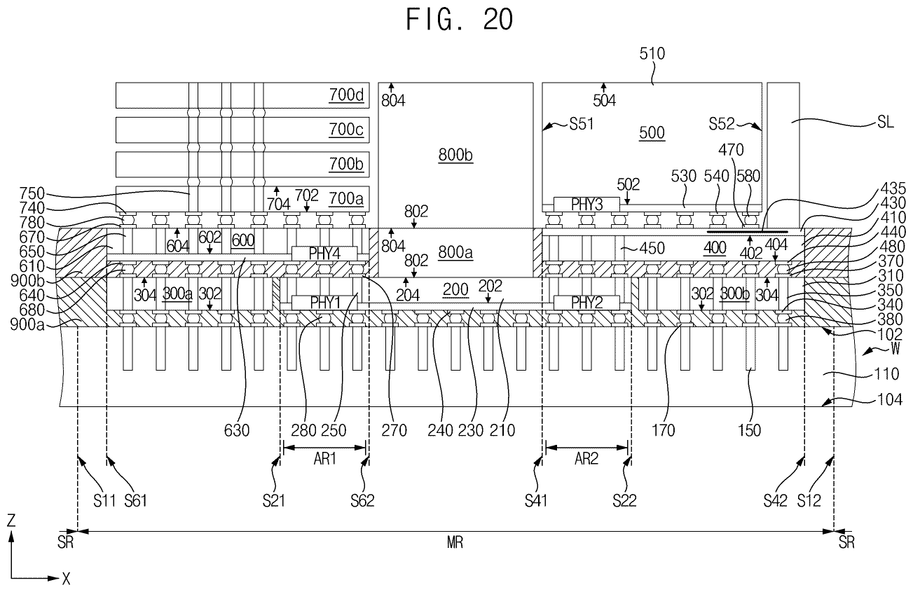

FIGS. 8 to 26 are views illustrating a method of manufacturing a semiconductor package in accordance with example embodiments. FIG. 8, FIG. 9, FIG. 11, FIG. 13, FIG. 17, FIG. 18, and FIGS. 20 to 26 are cross-sectional views illustrating a method of manufacturing a semiconductor package of FIG. 1. FIG. 10, FIG. 12, and FIG. 14 are plan views illustrating a method of manufacturing a semiconductor package of FIG. 1. FIG. 9 is a cross-sectional view taken along the line E-E′ in FIG. 10. FIG. 11 is a cross-sectional view taken along the line F-F′ in FIG. 12. FIG. 13 is a cross-sectional view taken along the line I-I′ in FIG. 14. FIG. 15 is an enlarged cross-sectional view illustrating the ‘G’ portion of FIG. 13. FIG. 16 is an enlarged cross-sectional view illustrating the ‘H’ portion of FIG. 13. FIG. 19 is an enlarged cross-sectional view illustrating the ‘J’ portion of FIG. 18.

Referring to FIG. 8, a wafer W having a plurality of interposers 100 may be provided.

In example embodiments, the interposer 100 may include a first substrate 110 providing a front surface 102 and a backside surface 104 opposite to the front surface 102. The first substrate 110 may include a plurality of mounting region MR and a scribe lane region SR at least partially surrounding the plurality of mounting regions MR. Later, the first substrate 110 may be cut by sawing process along the scribe lane region SR dividing the plurality of mounting region MR of the wafer W to be individualized into a plurality of substrate.

The interposer 100 may include a plurality of first lower pads 140, a plurality of first through vias 150 and a plurality of first upper pads 170. The interposer may be a silicon interposer having a plurality of wires formed therein. Electronic devices mounted on the interposer may be electrically connected through the plurality of wires. The interposer may provide a high-density interconnection between the electronic devices mounted on the interposer. In some embodiments, the interposer may be a redistribution interposer including a plurality of wirings, a plurality of metal vias and a plurality of insulation layers.

For example, the first substrate 110 may include a front surface 102 and backside surface 104 respectively extending in a first direction (X-direction) and a second direction (Y direction) perpendicular to the first direction (X-direction). The first substrate 110 may include a first side portion S11 and a second side portion S12 extending in the second direction (Y-direction) and facing each other. The first substrate 110 may include a third side portion S13 and a fourth side portion S14 extending in the first direction (X-direction) and facing each other. The first substrate may include a semiconductor material such as silicon, germanium, silicon-germanium, or a group III-V compound semiconductor such as gallium phosphide (GaP), gallium arsenide (GaAs), or gallium antimonide (GaSb).

The plurality of first through vias 150 may vertically penetrate the first substrate 110 extend from the front surface 102 and the backside surface 104 of the first substrate 110. For example, the plurality of first through vias may include through silicon vias.

The plurality of first upper pads 170 be provided on the front surface 102 along the XY direction as an array form. The plurality of first upper pads may be respectively in contact with second portions of the plurality of first through vias 150 opposed to the end portions. For example, the plurality of first upper pads may be conductive pad including a metal material for an electrical connection.

Referring to FIGS. 9 and 10, a first semiconductor chip 200 and a plurality of connection dies 300 may be mounted on the plurality of mounting regions MR of the wafer W providing the plurality of interposers 100. For example, the first semiconductor chip may be a logic chip including logic circuits. The logic chip may be a controller to control electronic devices mounted on the interposer. The first semiconductor chip may be a processor chip such as an ASIC as a host, such as a CPU, GPU, or SOC, or an application processor (AP).

The first semiconductor chip 200 may be mounted on a central portion of each of the plurality of mounting regions MR of the interposer 100. Later, the plurality of connection dies 300 may be provided on the front surface 102 of the interposer 100 adjacent to the side portions S11 and S12 of the interposer 100 with the first semiconductor chip 200 interposed therebetween.

A plurality of connection dies 300 may include a first die 300a and a second die 300b. For example, the first die 300a may be spaced apart from the first semiconductor chip 200 in the first direction (X direction) to be disposed adjacent to the first side portion S11 of the interposer 100. The second die 300b may be spaced apart from the first semiconductor chip 200 in the first direction (X direction) to be disposed adjacent to the second side portion S12 of the interposer 100.

The first semiconductor chip 200 and the plurality of connection dies 300 may be mounted on the interposer 100 by a flip chip bonding method. For example, the first semiconductor chip 200 may be mounted on the front surface 102 of the interposer 100 via a plurality of second conductive connection members 280 provided between the plurality of first upper pads 170 and the plurality of second lower pads 240, respectively. Also, the plurality of connection dies 300 may be mounted on the front surface 102 of the interposer 100 via a plurality of third conductive connection members 380 provided between the plurality of first upper pads 170 and the plurality of third lower pads 340, respectively. For example, the plurality of second conductive connection members and the plurality of third conductive connection members may be solder bumps containing or including a metal material.

The first semiconductor chip 200 may be mounted on the interposer 100 such that the front surface as an active surface 202 faces the interposer 100. For example, the second substrate 210 may include a front surface 202 and a backside surface 204 respectively extending in the first direction (X-direction) and the second direction (Y direction). The second substrate 210 may include a first side portion S21 and second side portion S22 extending in the second direction (Y direction) and facing each other. The second substrate 210 may include a third side portion S23 and a fourth side portion S24 extending in the first direction (X direction) and facing each other.

The second substrate 210 may provide or include a first physical layer PHY1 in a first region AR1 adjacent to the first side portion S21. Additionally, the second substrate 210 may provide or include a second physical layer PHY2 in a second region AR2 adjacent to the second side portion S22.

The physical layer may be an interface region for communication between electronic devices adjacently disposed in one package. For example, the physical layer may be a region for data transmission between various electronic devices such as controller chips (e.g., a GPU and CPU), memory devices such as DRAM and an optical engine included in one package. For example, the physical layer may be a region where a plurality of circuits and pads for input/output are provided to exchange data inside a chip.

The first semiconductor chip 200 and the plurality of connection dies 300 may include a plurality of through vias. For example, the first semiconductor chip 200 may include a plurality of second through vias 250, and the plurality of connection dies 300 may include a plurality of third through vias 350.

The plurality of second through vias 250 may include first conductive vias 250a and second conductive vias 250b. The plurality of second through vias 250 may be provided in the second substrate 210 to penetrate or extend into the front surface 202 and the backside surface 204 of the second substrate 210. Also, the plurality of third through vias 350 may vertically penetrate or extend into the third substrate 310 to connect the front surface 302 and the backside surface 304 of the third substrate 310. For example, the plurality of second through vias and the plurality of third through vias may include through silicon via (TSV).

The plurality of second through vias 250 may be provided in the first region AR1 and the second region AR2. The plurality of first conductive vias 250a may be provided in the first region AR1 to be overlapped with the first physical layer PHY1. The plurality of second conductive vias 250b may be provided in the second region AR2 to be overlapped with the second physical layer PHY2.

The first semiconductor chip 200 and the plurality of connection dies 300 may include a plurality of upper pads on each of the backside surface. For example, a plurality of second upper pads 270 of the first semiconductor chip 200 may be provided on the backside surface 204 of the second substrate 210. Also, a plurality of third pads 370 of the plurality of connection dies 300 may be provided on the backside surface 304 of the third substrate 310.

The plurality of second upper pads 270 may include a plurality of first conductive pads 270a and a plurality of second conductive pads 270b. The plurality of first conductive pads 270a may be provided on the plurality of first conductive vias 250a, and the plurality of second conductive pads 270b may be provided on the plurality of second conductive vias 250b.

Referring to FIGS. 11 and 12, the first molding portion 900a may be formed on the backside surface 104 of the interposer 100 to cover or overlap the first semiconductor chip 200 and the plurality of connection dies 300. For example, the first molding portion 900a may include a thermosetting resin such as an epoxy molding compounds (EMC) material. The first molding portion 900a may fill or be in a space between the first semiconductor chip 200 and the plurality of connection die 300 spaced apart from each other. The first molding portion 900a may expose the backside surface 204 of the first semiconductor chip 200 and the backside surface 304 of the plurality of connection die 300.

Referring to FIGS. 13 to 16, the photonic IC chip 400 may be mounted on the second die 300b and a first portion of the first semiconductor chip 200, and the second semiconductor chip 600 may be mounted on a first die 300a and a second portion of the first semiconductor chip 200. Additionally, the first dummy die 800a may be stacked on the backside surface 204 of the semiconductor chip 200 to be provided between the photonic IC chip 400 and the second semiconductor chip 600.

The photonic IC chip 400 may include a fourth substrate 410, a second front insulation layer 430, a plurality of fourth lower pads 440, a plurality of fourth through vias 450, a second backside insulation layer 460, a plurality of fourth upper pads 470 and a plurality of fourth conductive connection members 480. For example, the photonic IC chip may be a photonic integrated circuit (PIC). The PIC may be an optical chip that includes a plurality of optical elements that detect optical signals, transmit the optical signals, and convert the optical signals into electrical signals to process the optical signal.

As illustrated in FIGS. 13 and 14, the photonic IC chip 400 may include a first protruding portion PR1 protruding or extending from the second side portion S22 of the first semiconductor chip 200 and a first overlap portion OR1 excluding the first protruding portion PR1. For example, the first overlap portion OR1 of the photonic IC chip 400 may be mounted on a region adjacent to the second side portion S22 among the backside surface 204 of the first semiconductor chip 200 by a flip chip bonding method. For example, the first overlap portion OR1 of the photonic IC chip 400 may be mounted on the first portion of the first semiconductor chip 200 via a plurality of fourth conductive connection members 480 provided between the plurality of second conductive pads 270b and the plurality of second lower pads 440.

For example, the fourth substrate 410 may have a front surface 402 and a backside surface 404 respectively extending in the first direction (X-direction) and the second direction (Y direction). The fourth substrate 410 may include a first side portion S41 and a second side portion S42 extending in the second direction (Y direction) and facing each other. The fourth substrate 410 may include a third side portion S43 and a fourth side portion S44 extending in the second direction (X direction) and facing each other.

As illustrated in FIG. 13, the second front insulation layer 430 may cover or overlap the front surface 402 of the fourth substrate 410. As illustrated in FIG. 16, the second front insulation layer 430 may include a first interlayer insulation layer 430a and a second interlayer insulation layer 430b.

The first interlayer insulation layer 230a may provide or include a plurality of electronic elements 415 and a plurality of optical elements 437 provided on the front surface 402 of the fourth substrate 410 therein. For example, the plurality of optical elements 437 may include laser diodes to generate optical signals, optical switches to manage a path of the optical signals, optical modulators to modulate the optical signals and transmit data and photodetectors to convert the optical signals into electrical signals. Accordingly, the plurality of optical elements 437 may convert optical signal LS introduced or received from the optical fiber array unit FAU into the first electrical signal ES1. For example, the plurality of second electronic elements 415 may include electronic elements that process and transmit the first electrical signal ES1 converted from the plurality of optical elements 437.

Additionally, the second interlayer insulation layer 430b may have a plurality of second wirings 433 and an optical waveguide 435 therein. For example, the plurality of second wirings 433 may include a metal material for an electrical connection.

The optical waveguide 435 may be an optical path for transmitting the optical signal LS to the plurality of optical elements 437. For example, the second interlayer insulation layer 430b may be a cladding region having a relatively low refractive index, and the optical waveguide 435 may be a core region having a relatively high refractive index.

As illustrated in FIGS. 13 and 16, the plurality of fourth through vias 450 may be provided to penetrate or extend into the fourth substrate 410 and extend from the front surface 402 to the backside surface 404 of the fourth substrate 410. One end portion of each of the plurality of fourth through vias 450 may be in contact with each of the plurality of second wirings 433 connected to the plurality of fourth upper pads 470.

The plurality of fourth through vias 450 may be provided in the first overlap portion OR1 overlapped with the second region AR2. For example, the plurality of fourth through vias 450 may be provided in a region adjacent to the second side portion S42 overlapped with the second region AR2 of the first semiconductor chip 200. Accordingly, the plurality of fourth through vias 450 may be overlapped with the second physical layer PHY2 and the plurality of second conductive vias 250b provided on the second region AR2 of the first semiconductor chip 200.

The plurality of fourth lower pads 440 may be provided on the backside surface 404 along the XY direction as an array form. The plurality of fourth lower pads 440 may be provided on other end portions of each of the plurality of fourth through vias 450 opposite to the one end portion. Also, the plurality of fourth upper pads 470 may be provided on the front surface 402 of fourth substrate 410.

The second semiconductor chip 600 may include a sixth substrate 610, a fourth front insulation layer 630, a plurality of sixth lower pads 640, a plurality of fifth through vias 650, a plurality of fifth upper pads 670 and a plurality of sixth conductive connection members 680. For example, the second semiconductor chip may be a semiconductor chip that connects electrical signals between a plurality of memory chips and a controller chip and serves as a buffer to organize the electrical signals between a plurality of memory chips and a controller chip.

As illustrated in FIGS. 13 and 14, the second semiconductor chip 600 may include a second protruding portion PR2 protruding or extending from the first side portion S21 of the first semiconductor chip 200 and a second overlap portion OR2 excluding the second protruding portion PR2. The second overlap portion OR2 of the second semiconductor chip 600 may be mounted on a region adjacent to the first side S21 among the backside surface 204 of the first semiconductor chip 200 by a flip chip bonding method. For example, the second overlap portion OR2 of the second semiconductor chip 600 may be mounted on the backside surface 204 of the first semiconductor chip 200 via the plurality of sixth connection members 680 respectively provided between the plurality of first conductive pads 270a and the plurality of sixth lower pads 640.

The sixth substrate 610 may have a front surface 602 and a backside surface 604 respectively extending in the first direction (X-direction) and the second direction (Y direction). The sixth substrate 610 may include a first side portion S61 and a second side portion S62 extending in the second direction (Y direction) facing each other. The sixth substrate 610 may include a third side portion S63 and a fourth side portion S64 extending in the first direction (X direction) facing each other.

The sixth substrate 610 may include a fourth physical layer PHY4 in the second overlap portion OR2 adjacent to the second side portion S62. The fourth physical layer PHY4 may be overlapped with the first region AR1 providing or including the first physical layer PHY1 and the plurality of second conductive vias 250b.

As illustrated in FIGS. 13 and 15, the fourth front insulation layer 630 may cover or overlap the front surface 602 of the sixth substrate 610. The fourth front insulation layer 630 may include a first interlayer insulation layer 630a and a second interlayer insulation layer 630b. For example, the first interlayer insulation layer 630a may provide a plurality of electronic devices formed on the front surface 602 of the sixth substrate 610 therein. For example, a plurality of fourth electronic devices 615 may be provided on the front surface 602 of the sixth substrate 610. Additionally, a plurality of fourth wirings 633 may be provided in the second interlayer insulation layer 630b.

The plurality of sixth lower pads 640 may be provided on the front surface 602 of the sixth substrate 610. For example, the plurality of sixth lower pads 640 may be electrically connected to the plurality of fourth wirings 633.

The plurality of fifth through vias 650 may be provided to penetrate or extend into the sixth substrate 610 and from the front surface 602 to the backside surface 604 of the sixth substrate 610. One end portion of each of the plurality of fifth through vias 650 may be in contact with the plurality of fourth wirings 633 connected to the plurality of sixth lower pads 640.

The plurality of fifth upper pads 670 may be provided on the backside surface 604 of the sixth substrate 610. For example, the plurality of fifth upper pads 670 may be provided on other end portions of each of the plurality of fifth through vias 650 opposite to the one end portion.

Referring to FIG. 17, the second molding portion 900b may be formed on the first molding portion 900a to cover or overlap the photonic IC chip 400, the second semiconductor chip 600 and the first dummy die 800a. For example, the second molding portion 900b may include a thermosetting resin such as an epoxy molding compounds (EMC) material. The second molding portion 900b may fill or be in a space between the photonic IC chip 400, the second semiconductor chip 600 and the first dummy die 800a spaced apart from each other. The second molding portion 900b may expose the upper surfaces 402, 604 and 804 of the photonic IC chip 400, the second semiconductor chip 600 and the first dummy die 800a.

Referring to FIGS. 18 and 19, an electronic IC chip 500 may be mounted on the front surface 402 of the photonic IC chip 400, and a plurality of third semiconductor chip 700 may be mounted on the backside surface 604 of the second semiconductor chip 600. Additionally, a second dummy die 800b may be stacked on the upper surface 804 of the first dummy die 800a such that a lower surface 802 of the second dummy die 800b faces the first semiconductor chip 200.

In example embodiments, the electronic IC chip 500 may include a fifth substrate 510, a third front insulation layer 530, a plurality of fifth lower pads 540, and a plurality of fifth conductive connection members 580. For example, the electronic IC chip may be an electronic integrated circuit EIC. The EIC may convert an analog electrical signal introduced or received from the PIC into a digital electrical signal and convert a current electrical signal into a voltage electrical signal. The EIC may be a semiconductor chip including electronic elements that amplify the converted electrical signal.

The electronic IC chip 500 may be mounted on the photonic IC chip 400 by a flip chip bonding method. For example, the electronic IC chip 500 may be mounted on the front surface 402 of the IC chip 400 via a plurality of fifth conductive connection members 580 respectively provided between the plurality of fourth upper pads 470 and the plurality of fifth lower pads 540.

For example, the fifth substrate 510 may have a front surface 502 and a backside surface 504 respectively extending in the first direction (X-direction) and the second direction (Y direction). The fifth substrate 510 may include a first side portion S51 and a second side portion S52 extending in the second direction (Y direction) and facing each other. Although not illustrated in the figures, the fifth substrate 510 may include a third side portion S53 and a fourth side portion S54 extending in the first direction (X direction) and facing each other.

The fifth substrate 510 may include a third physical layer PHY3 on a region adjacent to the first side portion S51. The third physical layer PHY3 may be overlapped with the second region AR2 in which the second physical layer PHY2 and the plurality of second conductive vias 250b are provided and with which the plurality of fourth through vias 450 are overlapped.

Referring again to FIG. 19, the third front insulation layer 530 may cover or overlap the front surface 502 of the fifth substrate 510. The third front insulation layer 530 may include a first interlayer insulation layer 530a and a second interlayer insulation layer 530b. The first interlayer insulation layer 530a may include a plurality of electronic devices formed on the front surface 502 of the fifth substrate 510 therein. For example, a plurality of third electronic devices 515 may be provided on the front surface 502 of the fifth substrate 510. The second interlayer insulation layer 530b may provide or include a plurality of third wirings 533 therein.

The plurality of fifth lower pads 540 may be provided on the front surface 502 of the fifth substrate 510. For example, the plurality of fifth lower pads 540 may be electrically connected to the plurality of third wirings 533.

The optical signal LS may be transmitted to the first semiconductor chip 200 through the photonic IC chip 400 and the electronic IC chip 500. For example, the optical signal LS introduced or received from the optical fiber array FA may be transmitted to the plurality of optical elements 357 through the optical waveguide 435. The plurality of optical elements 357 may convert the optical signal LS into a first electrical signal ES1. The first electrical signal ES1 may be transmitted to the electronic IC chip 500. For example, the electronic IC chip 500 may amplify the first electrical signal ES1 and convert the current electrical signal into a voltage electrical signal. The first electrical signal ES1 may be transmitted from the third physical layer PHY3 of the electronic IC chip 500 to the first physical layer PHY1 of the first semiconductor chip 200 through the plurality of fourth through vias 450 of the photonic IC chip 400.

In example embodiments, the plurality of third semiconductor chips 700 may include first to fourth memory chips 700a, 700b, 700c and 700d. The plurality of third semiconductor chips 700 may include a plurality of seventh lower pads 740, a plurality of sixth through vias 750 and a plurality of seventh conductive connection members 780. For example, the plurality of third semiconductor chips may be an electronic device in which memory chips, such as a DRAM, are stacked and electrically connected with each other. For example, the plurality of third semiconductor chips may include a plurality of through silicon vias. For example, the second semiconductor chip and the plurality of third semiconductor chips may be a high bandwidth memory (HBM) device.

The plurality of third semiconductor chips 700 may be mounted on the second semiconductor chip 600 by a flip chip bonding method. For example, the plurality of third semiconductor chips 700 may be mounted on the backside surface 604 of the second semiconductor chip 600 via a plurality of seventh conductive connection members 780 respectively provided between the plurality of fifth upper pads 670 and the plurality of seventh lower pads 740. In this case, the lower surface 702 of the plurality of third semiconductor chips 700 may be mounted on the second semiconductor chip 600 such that the lower surfaces 702 of the plurality of third semiconductor chips 700 face the second semiconductor chip 600. Also, the plurality of seventh lower pads 740 may be provided on the lower surface 702 of the first memory chip 700a.

Referring to FIG. 20, a sacrificial layer (SL) may be attached to the front surface 402 of the photonic IC chip 400. The sacrificial layer SL may be provided on the second front insulation layer 430 to be adjacent to the second side S42 where the optical waveguide 435 is provided.

For example, the sacrificial layer may include a polymer adhesive. In some embodiments, a photolithography process may be performed to form a photoresist pattern.

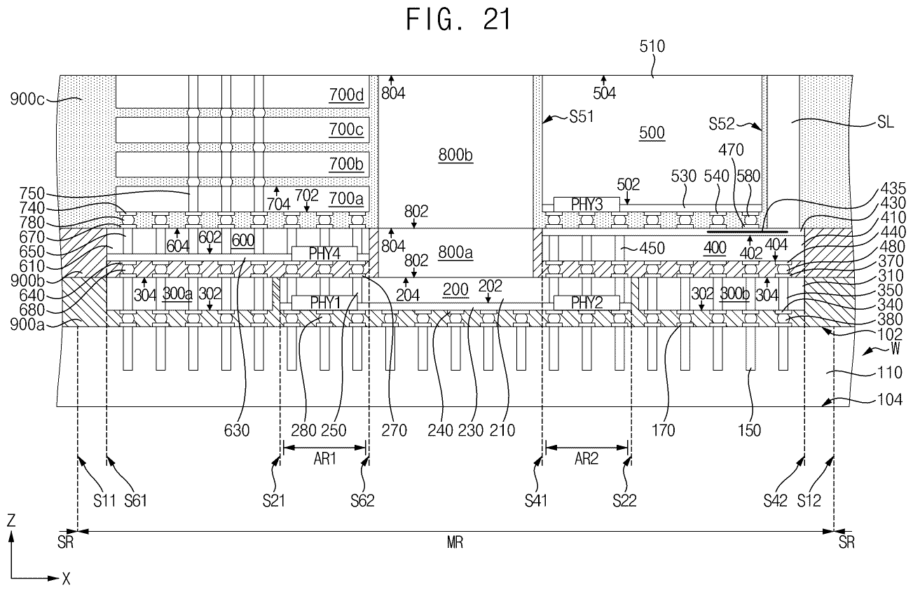

Referring to FIG. 21, the third molding portion 900c may be formed on the second molding portion 900b to cover or overlap the electronic IC chip 500, the plurality of third semiconductor chips 700, the second dummy die 800b and the sacrificial layer. For example, the third molding portion 900c may include a thermosetting resin such as an epoxy molding compounds (EMC) material. The third molding portion 900c may fill or be in a space between the electronic IC chip 500, the plurality of third semiconductor chips 700 and the second dummy die 800b spaced apart each other. The third molding portion 900c may expose the upper surfaces 504, 704, 804 of the electronic IC chip 500, the fourth memory chip 700d among the plurality of third semiconductor chip 700 and the second dummy die 800b.

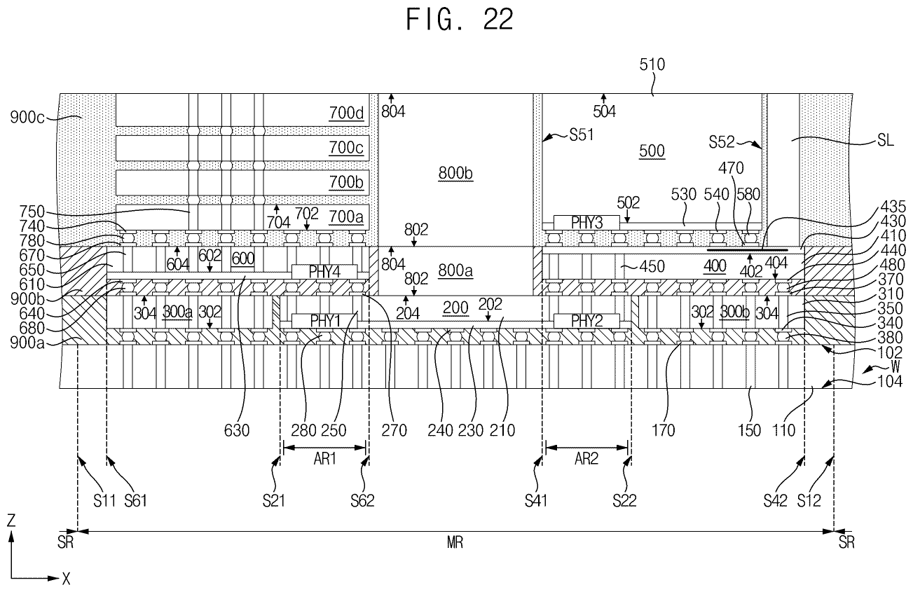

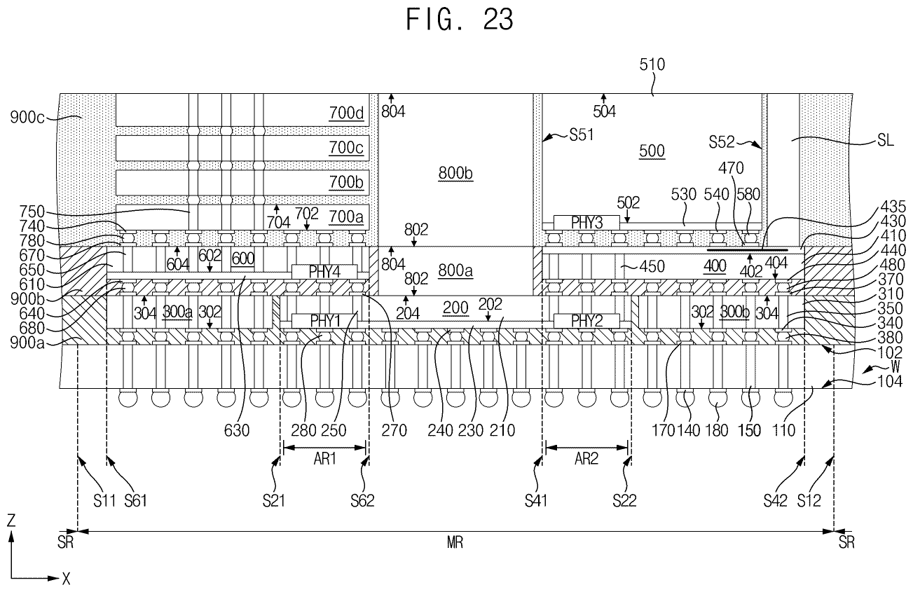

Referring to FIGS. 22 and 23, a portion of the backside surface 104 of the wafer W providing the plurality of interposers 100 may be removed to expose the second end portion of each of the plurality of first through vias 150. A plurality of first lower pads 140 and a plurality of first conductive members 180 may be sequentially attached to the second end portion of each of the plurality of first through vias 150.

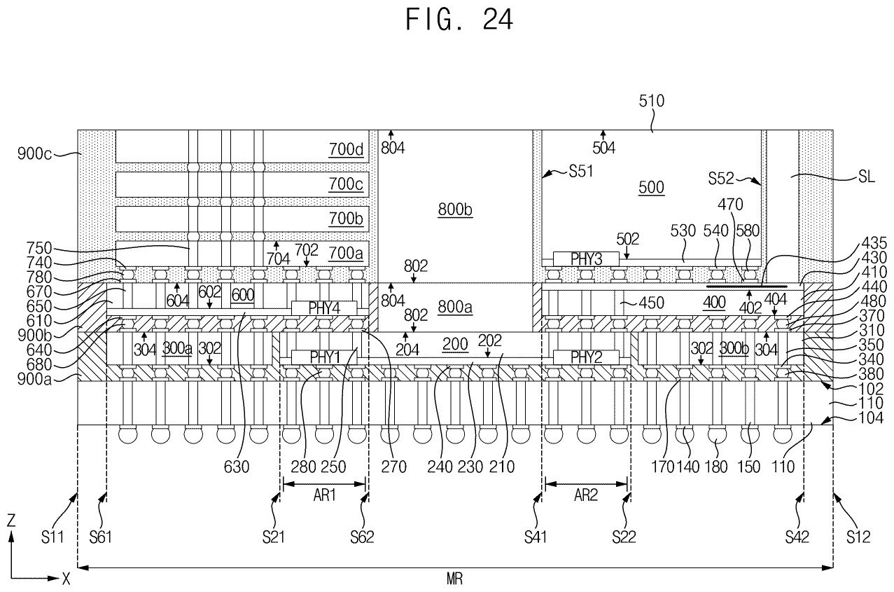

Referring to FIG. 24, the wafer W may be cut along the scribe lane region SR to form an individualized package. The wafer W may be cut by a sawing process.

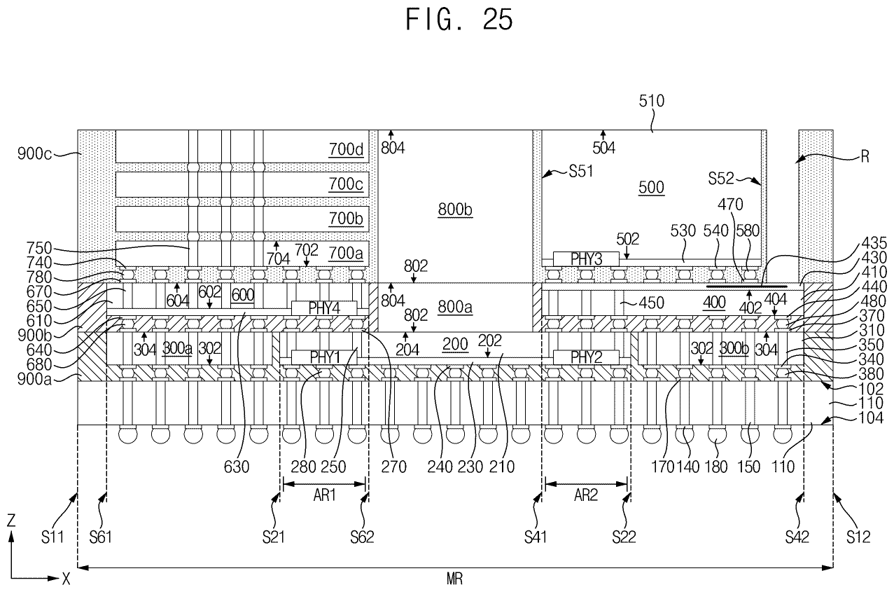

Referring to FIG. 25, the sacrificial layer SL provided in the third molding portion 900c may be removed to form a recess R exposing a portion of the second front insulation layer 430 of the photonic IC chip 400. The sacrificial layer SL may be removed by performing a wet etching process on the individualized package. For example, the recess R may be provided on a region adjacent to the second side S42 where the optical waveguide 435 is provided.

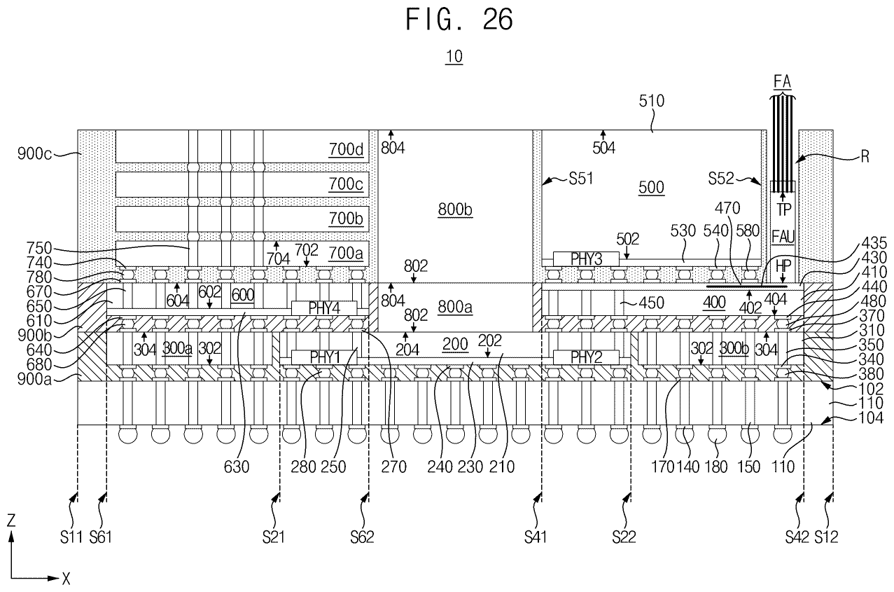

Referring to FIG. 26, a fiber array unit FAU may be inserted into the recess R to complete the semiconductor package 10 of FIG. 1.

The optical fiber array unit FAU may be provided on the second front insulation layer 430 adjacent to the second side portion S42 providing the optical waveguide 435. The fiber array unit FAU may include a head portion HP and a tail portion TP opposite to the head portion HP. The optical fiber array unit FAU may be provided on the second front insulation layer 430 such that the head portion HP faces the second front insulation layer 430. For example, the optical fiber array unit FAU may include an optical fiber array FA including a plurality of optical fibers as a medium through which the optical signal LS are transmitted. The optical fiber array FA may be provided on the tail portion TP of the optical fiber array unit FAU. A lens structure for transmitting the optical signal LS to the optical waveguide 435 may be provided on the head TP of the optical fiber array unit FAU.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present disclosure. Accordingly, all such modifications are intended to be included within the scope of example embodiments as defined in the claims.

What is claimed is:

1. A semiconductor package, comprising:
an interposer that extends in a first direction and comprises a plurality of lower pads and a plurality of upper pads;
a first semiconductor chip on the interposer, wherein the first semiconductor chip comprises a first side portion and a second side portion that extend in parallel with a second direction that is perpendicular to the first direction, wherein the first semiconductor chip comprises a first physical layer in a first region of the first semiconductor chip that is adjacent to the first side portion and a second physical layer in a second region of the first semiconductor chip that is adjacent to the second side portion;
a photonic integrated circuit (IC) chip comprising a plurality of first through vias that at least partially overlap the second region of the first semiconductor chip in a third direction perpendicular to the first direction and the second direction, wherein a first portion of the photonic IC chip is on the first semiconductor chip; and
an electronic IC chip on the photonic IC chip, wherein the electronic IC chip comprises a third physical layer that at least partially overlaps the second region of the first semiconductor chip in the third direction.

2. The semiconductor package of claim 1, further comprising:
an optical fiber array unit on the photonic IC chip and comprising a plurality of optical fibers.

3. The semiconductor package of claim 2, wherein the photonic IC chip comprises an optical waveguide configured to transmit an optical signal received from the plurality of optical fibers and an optical element configured to convert the optical signal into an electrical signal.

4. The semiconductor package of claim 1, further comprising:
a second semiconductor chip comprising a fourth physical layer that at least partially overlaps the first region of the first semiconductor chip in the third direction, wherein a second portion of the second semiconductor chip is on the first semiconductor chip.

5. The semiconductor package of claim 4, further comprising:
a plurality of third semiconductor chips on the second semiconductor chip, wherein the second semiconductor chip comprises a plurality of second through vias.

6. The semiconductor package of claim 5, further comprising:
a plurality of dummy dies that are on the first semiconductor chip and are between the photonic IC chip and the second semiconductor chip.

7. The semiconductor package of claim 6, wherein an upper surface of one of the plurality of dummy dies is coplanar with an upper surface of the electronic IC chip and an upper surface of one of the plurality of third semiconductor chips.

8. The semiconductor package of claim 5, further comprising:
a plurality of molding members that are on the interposer and at least partially overlap the first semiconductor chip, the photonic IC chip, and the electronic IC chip in the first direction.

9. The semiconductor package of claim 1, wherein the first semiconductor chip comprises a plurality of second through vias in the first region of the first semiconductor chip and the second region of the first semiconductor chip.

10. The semiconductor package of claim 1, further comprising:
a plurality of conductive connection members that are respectively on the plurality of lower pads of the interposer.

11. A semiconductor package, comprising:
an interposer that extends in a first direction and comprises a plurality of lower pads and a plurality of upper pads;
a first semiconductor chip on the interposer, wherein the first semiconductor chip comprises a first side portion and a second side portion that extends in parallel with a second direction that is perpendicular to the first direction, wherein the first semiconductor chip comprises a first physical layer in a first region of the first semiconductor chip that is adjacent to the first side portion and a second physical layer in a second region of the first semiconductor chip that is adjacent to the second side portion;
a photonic IC chip comprising a plurality of first through vias that at least partially overlap the second region of the first semiconductor chip in a third direction perpendicular to the first direction and the second direction, wherein a first portion of the photonic IC chip is on the first semiconductor chip; and
a second semiconductor chip comprising a fourth physical layer that at least partially overlaps the first region of the first semiconductor chip in the third direction, wherein a second portion of the second semiconductor chip is on the first semiconductor chip.

12. The semiconductor package of claim 11, further comprising:
an optical fiber array unit that is on the photonic IC chip and comprises a plurality of optical fibers.

13. The semiconductor package of claim 12, wherein the photonic IC chip comprises an optical waveguide configured to transmit an optical signal received from the plurality of optical fibers and a plurality of optical elements configured to convert the optical signal into an electrical signal.

14. The semiconductor package of claim 11, further comprising:
an electronic IC chip on the photonic IC chip.

15. The semiconductor package of claim 14, further comprising:
a plurality of third semiconductor chips on the second semiconductor chip, wherein the second semiconductor chip comprises a plurality of third through vias, and wherein the electronic IC chip comprises a third physical layer that at least partially overlaps the second region of the first semiconductor chip in the third direction.

16. The semiconductor package of claim 15, further comprising:
a first dummy die that is on the first semiconductor chip and is between the photonic IC chip and the second semiconductor chip; and
a second dummy die that is on the first dummy die and is between the electronic IC chip and at least one of the plurality of third semiconductor chips.

17. The semiconductor package of claim 16, further comprising:
a plurality of molding members that are on the interposer and at least partially overlap the first semiconductor chip, the photonic IC chip, the electronic IC chip, the second semiconductor chip, the plurality of third semiconductor chips, the first dummy die and the second dummy die in the first direction.

18. The semiconductor package of claim 11, wherein the first semiconductor chip comprises a plurality of second through vias in the first region and the second region.

19. The semiconductor package of claim 11, further comprising:
a plurality of conductive connection members that are respectively on the plurality of lower pads of the interposer.

20. A semiconductor package, comprising:
an interposer that extends in a first direction, the interposer comprising:
a first substrate,
a plurality of first lower pads on a backside surface of the first substrate,
a plurality of first upper pads on a front surface of the first substrate, and
a plurality of first through vias electrically connected to the plurality of first lower pads and to the plurality of first upper pads;
a first semiconductor chip comprising:
a second substrate comprising a first physical layer in a first region of the first semiconductor chip and a second physical layer in a second region of the first semiconductor chip,
a plurality of second lower pads on a front surface of the second substrate,
a plurality of second upper pads on a backside surface of the second substrate,
a plurality of second through vias in the first region and the second region, and
first conductive connection members that are respectively between the plurality of first upper pads and the plurality of second lower pads;
a photonic IC chip comprising:
an optical fiber array unit that comprises a plurality of optical fibers,
an optical waveguide configured to transmit an optical signal received from the plurality of optical fibers,
an optical element configured to convert the optical signal into an electrical signal, and
a plurality of third through vias that at least partially overlap the second region of the first semiconductor chip in a second direction that is perpendicular to the first direction, wherein a first portion of the photonic IC chip is on the first semiconductor chip;
an electronic IC chip comprising:
a third substrate that comprises a third physical layer that at least partially overlaps the second region of the first semiconductor chip in the second direction, and
a plurality of third lower pads on a front surface of the third substrate,
a plurality of third conductive connection members that are respectively between a plurality of third upper pads of the photonic IC chip and the plurality of third lower pads;
a second semiconductor chip comprising:
a fourth substrate that comprises a fourth physical layer that at least partially overlaps the first region of the first semiconductor chip in the second direction, and
a plurality of fourth lower pads on a front surface of the fourth substrate,
a plurality of fourth conductive connection members that are respectively between the plurality of second upper pads and the plurality of fourth lower pads;
a first die that is on the interposer and is spaced apart from the first semiconductor chip, wherein a first protruding portion of the photonic IC chip that extends from the first semiconductor chip is on the first die; and
a second die that is on the interposer and is spaced apart from the first semiconductor chip, wherein a second protruding portion of the second semiconductor chip that extends from the first semiconductor chip is on the second die.
